(19) United States
(12) Patent Application Publication
(10) Pub. No.: US 2026/0038542 A1
(43) Pub. Date: Feb. 5, 2026

(54) CROSS-POINT MEMORY STRUCTURES, AND RELATED METHODS OF CONSTRUCTION AND OPERATION

(71) Applicant: Micron Technology, Inc., Boise, ID (US)

(72) Inventors: Rajasekhar Venigalla, Boise, ID (US); Matthew Thorum, Boise, ID (US); Farrell Martin Good, Meridian, ID (US); Stephen W. Russell, Boise, ID (US); Fabio Pellizzer, Boise, ID (US); Zhao Zhao, Meridian, ID (US)

(21) Appl. No.: 19/268,423

(22) Filed: Jul. 14, 2025

Related U.S. Application Data
(60) Provisional application No. 63/677,974, filed on Jul. 31, 2024.

(51) Int. Cl. G11C 5/06; H01L 21/768; H10B 63/00; H10N 70/00

(52) U.S. Cl. CPC G11C 5/063; H01L 21/76843; H01L 21/76877; H10B 63/34; H10B 63/845; H10N 70/021; H10N 70/826; H10N 70/841

(57) ABSTRACT

Memory devices, such as three-dimensional cross-point memory devices, and methods of manufacturing such devices are addressed. Multiple methods of manufacturing such memory devices are described to provide improved protection of replacement gate structures, such as word lines and in some examples, word line liners. These include processing flows which form one or more additional barrier structures between structures subject to at least partial removal during the processing flow; wherein some portion of the additional barrier structure(s) will remain at the end of manufacturing.

### PRIORITY APPLICATION

This application claims the benefit of priority to U.S. Provisional Application Ser. No. 63/677,974, filed Jul. 31, 2024, which is incorporated herein by reference in its entirety.

### BACKGROUND

Memory structures are semiconductor circuits that provide electronic storage of data for an associated “host” system (e.g., a processor or other logic circuitry, a computer, or other electronic device). Memory structures may be formed integral to an associated host system, or portion thereof, or may be formed independently as memory devices. Memory structures may be formed as either volatile or non-volatile memory. Of these, volatile memory requires power to maintain data, and includes devices such as, static random-access memory (SRAM), dynamic random-access memory (DRAM), or synchronous dynamic random-access memory (SDRAM), among others. Non-volatile memory can retain stored data when not powered, and includes devices such as flash memory, electrically erasable programmable ROM (EEPROM), erasable programmable ROM (EPROM), resistance variable memory, such as phase change random-access memory (PCRAM), resistive random-access memory (RRAM), or magnetoresistive random-access memory (MRAM), among others.

Host systems typically include a host processor, a first amount of main memory (e.g., often volatile memory, such as DRAM) to support the host processor, and one or more storage systems (e.g., often non-volatile memory, such as flash memory) that provide additional storage to retain data in addition to or separate from the main memory.

As the needs for have increased for memory providing larger storage capacities, and at the same time increased storage efficiency (storage capacity per spatial area), memory structures having multiple layers of memory cells forming a three-dimensional (“3D”) array of memory cells (also termed herein a “memory array”) have become increasingly common. Various forms of memory, including, for example, both non-volatile memory, such as flash, and volatile memory, such as DRAM, have been implemented as 3D memory structures.

Another configuration of memory, however, known generally as cross-point memory structures, have become desirable due to potentially relatively simpler manufacturing and greater storage efficiency. For avoidance of doubt, the referenced cross-point memory structures, are not to be confused with “X-point®” memory, which is a registered trademark of Intel corporation associated with a specific cross-point memory technology.

Cross-point memory includes an array of multiple word lines extending generally within multiple first planes, the word lines typically extending generally parallel to one another in a first direction, and an array of multiple bit lines extending generally within multiple second planes, the multiple bit lines generally intersecting with the first planes of word lines (and in most cases extending generally orthogonal to the first planes of word lines). Proximate the general intersection of a word line with a bit line, there may typically be a discrete programmable element having a variable property associated with an electrical state which, in a single bit memory cell is indicative of a 1 or 0, or in a multiple bit memory cell is indicative of one of more than two electrical states, indicating one of multiple possible bits.

Always increasing demands for greater memory capacity and improved speed, as well as reliability during the manufacturing process and in the finished device.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 depicts a schematic of an example configuration for a planar cross-point memory array.

FIGS. 2A-2C depicts layout representations of cross-point memory arrays, in which FIG. 2A depicts an example memory array from a top view; while FIGS. 2B-2C depicts the example memory array from common side views.

FIGS. 3A-3B depict a multi-tier structure of an example structure suitable for use in forming a three-dimensional cross-point memory array; depicted in FIG. 3A from a side view, and depicted in FIG. 3B from a top view, and after initial processing.

FIGS. 4A-4M depict successive representative stages of an example process flow for forming structures of a memory array, such as a cross-point memory array, in which each figure depicts representative views of a word line tier and a dielectric tier at respective stages of the example process flow, from a respective plan view from above the respective tier.

FIGS. 5A-5H depict successive representative stages of another example process flow for forming structures of a memory array, such as a cross-point memory array, in which, again, each figure depicts representative views of a word line tier and a dielectric tier at respective stages of the example process flow, from a respective plan view from above the respective tier.

FIGS. 6A-D depicts example cross-sectional views of the surfaces surrounding a pier opening at selected stages of the example process flow of FIGS. 5A-5G.

FIG. 7 is a flowchart describing a method for forming structures of the memory array such as described relative to FIGS. 4A-4M.

FIG. 8 is a flowchart describing a method for forming structures of the memory array such as described relative to FIGS. 5A-5H.

FIG. 9 depicts a block diagram representation of an example electronic system that may incorporate one or more memory arrays constructed in accordance with the present disclosure.

### DETAILED DESCRIPTION

This specification addresses multiple memory structures which may be implemented in discrete memory devices (individually packaged, or packaged as a multichip device), or in one or more memory arrays implemented on a wafer (or portion thereof) comprising, for example, non-memory related structures and circuitry. Unless indicated otherwise by context, the terms “memory structures” and “memory devices” are used interchangeably with respect to the described structures, wherever the structures may be implemented.

In 3D memory structures, as noted above, memory cells are typically located in different levels, for example memory layers or tiers. These memory layers or tiers are separated from one another by separation layers or tiers, which in many examples are formed of primarily of one or more dielectric materials, which facilitates the memory cells being formed in contact with the dielectric separation layers or tiers, which for intermediate memory tiers sandwich the memory cell tiers.

In the described cross-point memory devices, each memory cell includes a configurable memory element which may be programmed to one of multiple physical states associated with a respective electrical (or other) property, and therefore associated with a data state. For purposes of the present example, the described configurable memory elements are variable state memory elements in which different states of the memory cell represent respective data states. For purposes of the present examples, the variable state memory elements will be described in the context of materials which exhibit variable electrical resistance associated with different physical states, and thus will be discussed in the present examples as variable resistance memory cells. Example variable resistance memory cells are described as including a chalcogenide variable resistance memory material as the configurable memory element. As known to persons skilled in the art, chalcogenides are combinations or alloys of certain materials, commonly including combinations of two or more of selenium (Se), tellurium (Te), arsenic (As), antimony (Sb), carbon (C), germanium (Ge), silicon (Si), and/or indium (In). In some examples, chalcogenide material by include additional elements such as one or more of hydrogen (H), oxygen (O), nitrogen (N), chlorine (Cl), or fluorine (F), in either atomic or molecular form. Notwithstanding the description of variable resistance memory cells in the present examples, other forms of variable state memory cells, may exhibit different measurable electrical properties, or other properties (magnetism, spin, quantum properties), and the present description expressly contemplates use of such other forms of variable state memory cells.

As is known to persons skilled in the art, chalcogenide elements are known for use in phase change memory elements, in which a physical phase change may be induced in the chalcogenide element. For example, chalcogenide-containing elements may change between a relatively amorphous—disordered—state, and a relatively crystalline—ordered—state. In some examples, these physical phase states may be characterized by different resistive properties, such that measurement of the resistance across the chalcogenide elements identifies the data state associated with the physical state of each phase change memory element. In some examples, properties of the chalcogenide-containing storage element other than electrical resistance may be measured to identify one or more data states associated with the physical state of each phase change memory element.

One desirable technique for forming such cross-point memory structures is that generally termed as a “replacement gate” method, in which a placeholder material is used during initial processing of a stacked memory structure for ease of processing to form initial structures; and then the placeholder material is selectively removed, and replaced, at least in part, by metal or metal alloy structures, such as to form, for example word lines and other conductive structures.

Though such processing provides substantial advantages during manufacture, subsequent manufacturing steps can still expose the replacement metal, and metal liner materials to chemistries which will attack either or both types of material, and which can lead to an increase for example, in word line resistance, or word line failure. Such increased resistance, when present, is detrimental to the functioning of the completed memory structure.

Accordingly, the present disclosure addresses multiple methods of forming a cross-point memory structure which provide improved protection of replacement metal structures, such as word lines and word line liners, during the manufacturing process. Described herein are multiple processing flows which include example ways of forming one or more additional barrier structures between one or more structures subject to at least partial removal during the processing flow, and wherein some portion of the additional barrier structure(s), will remain at the end of processing. In some examples, portions of the additional barrier structure may remain at locations proximate the word line barrier material. Such methods, and the resulting memory structures, are believed to both improve the manufacturing process, and potentially the yield of suitable devices resulting from such processes; as well as improving the electrical integrity and performance of the completed memory structures.

In the following discussion, various structures and features of the drawings are indicated by respective reference numerals. In some cases, structures being referred to in later figures may be essentially the same as, or directly comparable to, structures discussed relative to prior figures. In such circumstances, for clarity of description, the reference numerals from the earlier figures will be used in the subsequent drawings.

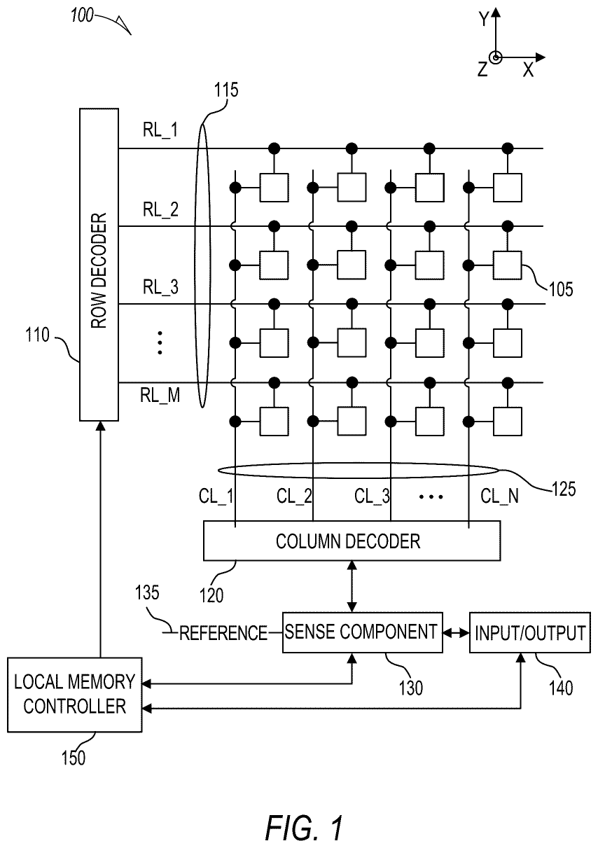

FIG. 1 depicts an example configuration of a memory structure 100 including a cross-point memory array 102. Memory structure 100 includes a local memory controller 150, along with the decoding and sensing circuitry used in operating memory structure 100. Such a memory structure 100 may be implemented in a discrete memory die (or “memory chip”), as may be individually packaged, or as may be combined with other die (potentially including other memory die and/or other semiconductor die or interface devices); and may form a part of a larger microelectronic device (i.e., a computer, phone, controller, etc.). Alternatively, the memory structure 100 may be one of multiple structures formed on an individual semiconductor die or wafer, such as, in one example, cache memory formed on a semiconductor die also containing one or more processor cores, or other logic structures. In the context of the present specification, each of these example memory structures, however implemented, constitutes a “memory device.”

Memory structure 100 contains multiple memory cells 105 coupled between a respective row line (RL-1, RL-2 . . . . RL-M), and a respective column line (CL-1, CL-2 . . . . CL-M). The memory cells 105 are configured to be programmable to store one of multiple logic states. In a single bit memory cell, a memory cell will be programmed to one of two possible logic states (0 or 1) to store a single bit of data. Though, as described earlier herein, in another example, in which memory cells 105 are implemented as multiple bit memory cells, each memory cell 105 will be implemented to store more than one bit of information at a time through additional logic states (00, 01, 10, 11, for example).

Memory cells 105 store the logic states through use of a configurable material within the cell (also referred to as a “memory element” or “storage element”), which is configurable to one of multiple states, each state associated with a respective logic state. For purposes of the present example, the configurable material/memory element within each of memory cells 105 may include a chalcogenide alloy as discussed above, to form a phase change memory cell. For purposes of the present examples, such a phase change memory cell may be placed in one of multiple possible phase states, each phase state associated with a logic state, as described above. For purposes of the present example, each phase state may determined by an electrical measurement, for example, a resistivity measurement of the memory element, to identify the phase state, and thus the logic state. In some examples, a logic 0 may be indicated by the memory element in a RESET state (for example, a relatively amorphous, disordered state), and a logic 1 may be indicated by the memory in a SET state (for example, a relatively crystalline, ordered state). In some systems, additional phase states may be achievable, and may be used to identify one or more additional logic states. Additionally, other properties may be measured in place of resistivity, to determine a logic phase state of the memory element.

The memory array 102 may include access lines (here, row lines 115, extending along an illustrative x-direction; and column lines 125, each extending along an illustrative y-direction), arranged in a pattern, such as a grid-like pattern. Access lines may be formed with one or more conductive materials. For example, as described below, where the access lines are word lines or bit lines, the access line material may be tungsten, or another metal or metallic compound with similar properties. In some examples, row lines 115 (RL_1, RL_2 to RL_M, etc.), or some portion thereof, may be referred to as word lines. In some examples, column lines 125 (CL-1, CL_2 to CL_N, etc.), or some portion thereof, may be referred to as digit lines or bit lines. Such word lines extend in first planes, and in a first direction, and each word line extends to respective first pluralities of memory cells in a respective memory tier; while the bit lines extend within second planes and in a second direction, and extends to respective second pluralities of memory cells distributed across multiple memory tiers; such that each word line extends proximate multiple bit lines, and that each bit line extends proximate multiple word lines.

Memory cells 105 may be positioned at proximity intersections of access lines, such as row lines 115 and the column lines 125. In some examples, memory cells 105 may also be arranged (e.g., addressed) along an illustrative z-direction, such as in an implementation of sets of memory cells 105 being located at different levels (e.g., layers, decks, planes, tiers) along the illustrative z-direction. In some examples, a memory structure 100 that includes memory cells 105 at different levels may be supported by a different configuration of access lines, decoders, and other supporting circuitry than shown.

Operations such as read operations and write operations may be performed on the memory cells 105 by activating access lines such as one or more of a row line 115 or a column line 125, among other access lines associated with alternative configurations. For example, by activating a row line 115 and/or a column line 125 (e.g., applying a voltage to the row line 115 or the column line 125), a memory cell 105 may be accessed in accordance with their proximity intersection. An intersection of a row line 115 and a column line 125, among other access lines, in various two-dimensional or three-dimensional configuration may be referred to as an address of a memory cell 105. In some examples, an access line may be a conductive line coupled with a memory cell 105 and may be used to perform access operations on the memory cell 105. In some examples, the memory structure 100 may perform operations responsive to commands, which may be issued by a host device coupled with the memory structure 100 or may be generated by the memory structure 100 (e.g., by a local memory controller 150).

During a write operation (e.g., a programming operation) of a self-selecting or thresholding memory cell 105, a polarity used for a write operation may influence (e.g., determine, set, or program) a behavior or characteristic of the material of the memory cell 105, such as a thresholding characteristic (e.g., a threshold voltage) of the material. A difference between thresholding characteristics of the material of the memory cell 105 for different logic states stored by the material of the memory cell 105 (e.g., a difference between threshold voltages when the material is storing a logic state ‘0’ versus a logic state ‘1’) may correspond to a read window of the memory cell 105).

Accessing the memory cells 105 may be controlled through one or more decoders, such as a row decoder 110 or a column decoder 120, among other examples. For example, a row decoder 110 may receive a row address from the local memory controller 150 and activate a row line 115 based on the received row address. A column decoder 120 may receive a column address from the local memory controller 150 and may activate a column line 125 based on the received column address.

The sense component 130 may be operable to detect a state (e.g., a material state, a resistance state, a threshold state) of a memory cell 105 and determine a logic state of the memory cell 105 based on the detected state. The sense component 130 may include one or more sense amplifiers to convert (e.g., amplify) a signal resulting from accessing the memory cell 105 (e.g., a signal of a column line 125 or other access line). The sense component 130 may compare a signal detected from the memory cell 105 to a reference 135 (e.g., a reference voltage, a reference charge, a reference current). The detected logic state of the memory cell 105 may be provided as an output of the sense component 130 (e.g., to an input/output component 140), and may indicate the detected logic state to another component of the memory structure 100 or to a host device coupled with the memory structure 100.

The local memory controller 150 may control the accessing of memory cells 105 through the various components (e.g., a row decoder 110, a column decoder 120, a sense component 130, among other components). In some examples, one or more of a row decoder 110, a column decoder 120, and a sense component 130 may be co-located with the local memory controller 150. The local memory controller 150 may be operable to receive information (e.g., commands, data) from one or more different controllers (e.g., an external memory controller associated with a host device, another controller associated with the memory structure 100), translate the information into a signaling that can be used by the memory structure 100, perform one or more operations on the memory cells 105 and communicate data from the memory structure 100 to a host device based on performing the one or more operations. The local memory controller 150 may generate row address signals and column address signals to activate access lines such as a target row line 115 and a target column line 125. The local memory controller 150 also may generate and control various signals (e.g., voltages, currents) used during the operation of the memory structure 100. In general, the amplitude, the shape, or the duration of an applied signal discussed herein may be varied and may be different for the various operations discussed in operating the memory structure 100.

The local memory controller 150 may be operable to perform one or more access operations on one or more memory cells 105 of the memory structure 100. Examples of access operations may include a write operation, a read operation, a refresh operation, a precharge operation, or an activate operation, among others. In some examples, access operations may be performed by or otherwise coordinated by the local memory controller 150 in response to access commands (e.g., from a host device). The local memory controller 150 may be operable to perform other access operations not listed here or other operations related to the operating of the memory structure 100 that are not directly related to accessing the memory cells 105.

As discussed above, in some examples, example memory structure 100 may include a memory array 102 of memory cells 105 arranged in a three-dimensional architecture that includes memory cells 105 arranged according to different levels (e.g., layers, decks, tiers). For example, vertically offset levels of memory cells 105 may be separated by intervening levels of dielectric materials such that the memory cells 105 are formed in contact with the dielectric material levels.

The memory structure 100 may include any quantity of non-transitory computer-readable media that support memory cell protective layers in a three-dimensional memory array. For example, a local memory controller 150, a row decoder 110, a column decoder 120, a sense component 130, or an input/output component 140, or any combination thereof may include or may access one or more non-transitory computer-readable media storing instructions (e.g., firmware) for performing the functions ascribed herein to the memory structure 100. For example, such instructions, if executed by the memory structure 100, may cause the memory structure 100 to perform one or more associated functions as described herein.

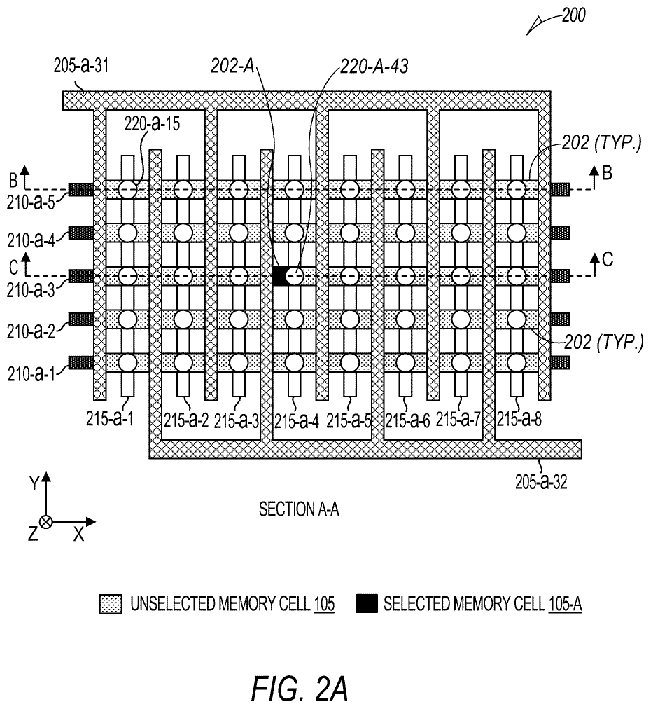

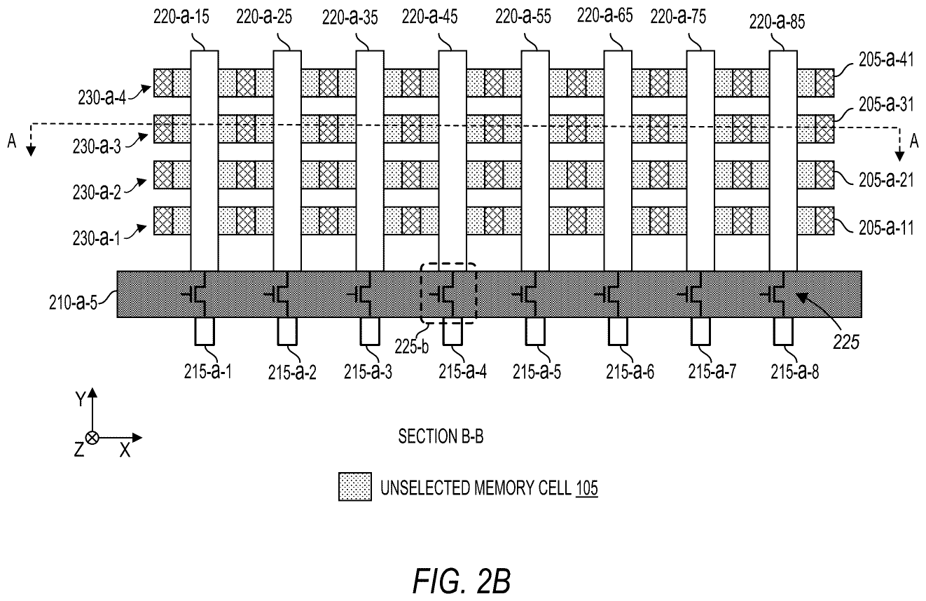

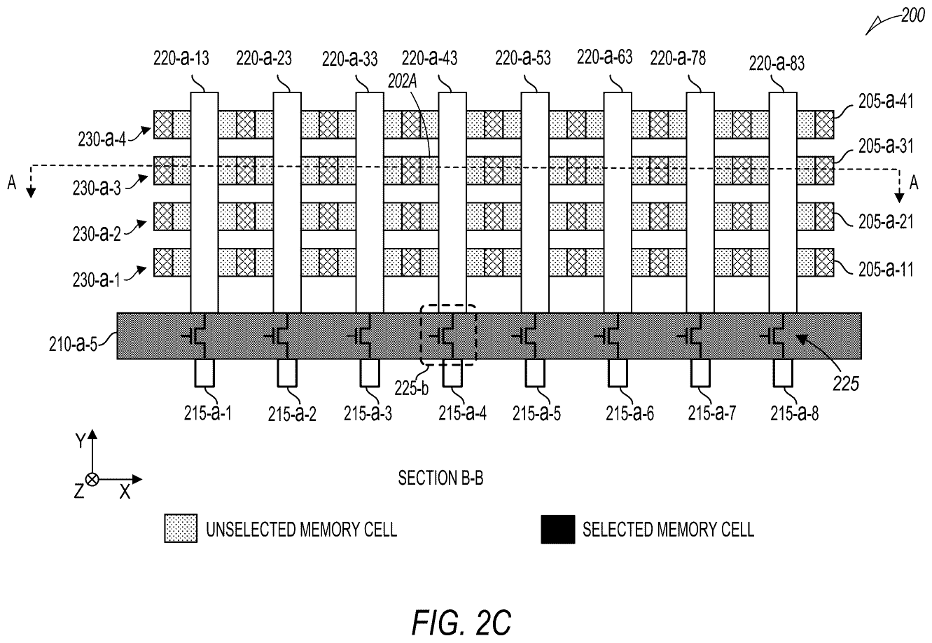

Referring now to FIGS. 2A-2C, the Figures depict an example memory array 200 that supports memory cell layers in a three-dimensional memory array in accordance with examples as disclosed herein. The memory array 200 may be included in a memory structure 100, and illustrates an example of a three-dimensional arrangement of cross-point memory cells 202 that may be accessed by various conductive structures (e.g., access lines). FIG. 2A depicts a top section view (e.g., Section A-A) of the memory array 200 relative to a cut plane A-A as shown in FIGS. 2B and 2C. FIG. 2B illustrates a side section view (e.g., Section B-B) of the memory array 200 relative to a cut plane B-B as shown in FIG. 2A. FIG. 2C illustrates a side section view (e.g., Section C-C) of the memory array 200 relative to a cut plane C-C as shown in FIG. 2A. The section views provide hope and examples of cross-sectional views of the memory array 200 with some aspects (e.g., dielectric structures) removed for clarity. Elements of the memory array 200 may be described relative to an x-direction, a y-direction, and a z-direction, as illustrated in each of FIGS. 2A, 2B, and 2C. Although some elements included in FIGS. 2A, 2B, and 2C are labeled with a numeric indicator, other corresponding elements are not labeled, although they are the same or would be understood to be similar, in an effort to increase visibility and clarity of the depicted features. Further, although some quantities of repeated elements are shown in the illustrative example of memory array 200, techniques in accordance with examples as described herein may be applicable to any quantity of such elements, or ratios of quantities between one repeated element and another.

In the example of memory array 200, memory cells 202 and word lines 205 may be distributed along the z-direction according to levels 230 (e.g., layers, planes, tiers, as illustrated in FIGS. 2B and 2C). In some examples, the z-direction may be orthogonal to a substrate (not shown) of the memory array 200, which may be below the illustrated structures along the z-direction. Although the illustrative example of memory array 200 includes four levels 230, a memory array 200 in accordance with examples as disclosed herein may include any quantity of one or more levels 230 (e.g., 64 levels, 128 levels, and greater) along the z-direction.

Each word line 205 may be an example of a portion of an access line that is formed by one or more conductive materials (e.g., one or more metal portions, one or more metal alloy portions). As illustrated, a word line 205 may be formed in a comb structure, including portions (e.g., projections, tines) extending along the y-direction through gaps (e.g., alternating gaps) between pillars 220. For example, as illustrated, the memory array 200, may include two word lines 205 per level 230 (e.g., according to odd word lines 205-a-n1 and even word lines 205-a-n2 for a given level, n), where such word lines 205 of the same level 230 may be described as being interleaved (e.g., with portions of an odd word line 205-a-n1 projecting along the y-direction between portions of an even word line 205-a-n2, and vice versa). In some examples, an odd word line 205 (e.g., of a level 230) may be associated with a first memory cell 202 on a first side (e.g., along the x-direction) of a given pillar 220 and an even word line (e.g., of the same level 230) may be associated with a second memory cell 202 on a second side (e.g., along the x-direction, opposite the first memory cell 202) of the given pillar 220. Thus, in some examples, memory cells 202 of a given level 230 may be addressed (e.g., selected, activated) in accordance with an even word line 205 or an odd word line 205.

Each pillar 220 may be an example of a portion of an access line (e.g., a conductive pillar portion) that is formed by one or more conductive materials (e.g., one or more metal portions, one or more metal alloy portions). As illustrated, the pillars 220 may be arranged in a two-dimensional array (e.g., in an x-y plane) having a first quantity of pillars 220 along a first direction (e.g., eight pillars along the x-direction, eight rows of pillars), and having a second quantity of pillars 220 along a second direction (e.g., five pillars along the y-direction, five columns of pillars). Although the illustrative example of memory array 200 includes a two-dimensional arrangement of eight pillars 220 along the x-direction and five pillars 220 along the y-direction, a memory array 200 in accordance with examples as disclosed herein may include any quantity of pillars 220 along the x-direction and any quantity of pillars 220 along the y-direction. Further, as illustrated, each pillar 220 may be coupled with a respective set of memory cells 202 (e.g., along the z-direction, one or more will memory cells 202 for each level 230). A pillar 220 that extends along the z-direction may have a cross-sectional area in an x-y plane. Although illustrated with a circular cross-sectional area in the x-y plane, a pillar 220 may be formed with a different shape, such as having an elliptical, square, rectangular, polygonal, or other cross-sectional area in an x-y plane.

The memory cells 202 each may include a chalcogenide material. In some examples, the memory cells 202 may be examples of thresholding memory cells. Each memory cell 202 may be accessed (e.g., addressed, selected) according to a proximate intersection between a word line 205 (e.g., a level selection, which may include an even or odd selection within a level 230) and a pillar 220 at the memory element. For example, as illustrated, a selected memory cell 202-a of the level 230-a-3 may be accessed according to such a proximate intersection between the pillar 220-a-43 and the word line 205-a-32.

A memory cell 202 may be accessed (e.g., written to, read from) by applying an access bias (e.g., an access voltage, Vaccess, which may be a positive voltage or a negative voltage) across the memory cell 202. In some examples, an access bias may be applied by biasing a selected word line 205 with a first voltage (e.g., Vaccess/2) and by biasing a selected pillar 220 with a second voltage (e.g., −Vaccess/2), which may have an opposite sign relative to the first voltage. Regarding the selected memory cell 202-a, a corresponding access bias (e.g., the first voltage) may be applied to the word line 205-a-32, while other unselected word lines 205 may be grounded (e.g., biased to 0V). In some examples, a word line bias may be provided by a word line driver (not shown) coupled with one or more of the word lines 205.

To apply a corresponding access bias (e.g., the second voltage) to a pillar 220, the pillars 220 may be configured to be selectively coupled with a sense line 215 (e.g., a digit line, a column line, an access line extending along the y-direction) via a respective transistor 225 coupled between (e.g., physically, electrically) the pillar 220 and the sense line 215. In some examples, the transistors 225 may be vertical transistors (e.g., transistors having a channel along the z-direction, transistors having a semiconductor junction along the z-direction), which may be formed above the substrate of the memory array 200 using various techniques (e.g., thin film techniques). In some examples, a selected pillar 220, a selected sense line 215, or a combination thereof may be an example of a selected column line 125 described with reference to FIG. 1 (e.g., a bit line).

The transistors 225 (e.g., a channel portion of the transistors 225) may be activated by gate lines 210 (e.g., activation lines, selection lines, a row line, an access line extending along the x-direction) coupled with respective gates of a set of the transistors 225 (e.g., a set along the x-direction). In other words, each of the pillars 220 may have a first end (e.g., towards the negative z-direction, a bottom end) configured for coupling with an access line (e.g., a sense line 215). In some examples, the gate lines 210, the transistors 225, or both may be considered to be components of a row decoder 110 (e.g., as pillar decoder components). In some examples, the selection of (e.g., biasing of) pillars 220, or sense lines 215, or various combinations thereof, may be supported by a column decoder 120, or a sense component 130, or both.

To apply the corresponding access bias (e.g., −Vaccess/2) to the pillar 220-a-43, the sense line 215-a-4 may be biased with the access bias, and the gate line 210-a-3 may be grounded (e.g., biased to 0V) or otherwise biased with an activation voltage. In an example where the transistors 225 are n-type transistors, the gate line 210-a-3 being biased with a voltage that is relatively higher than the sense line 215-a-4 may activate the transistor 225-a (e.g., cause the transistor 225-a to operate in a conducting state), thereby coupling the pillar 220-a-43 with the sense line 215-a-4 and biasing the pillar 220-a-43 with the associated access bias. However, the transistors 225 may include different channel types, or may be operated in accordance with different biasing schemes, to support various access operations.

In some examples, unselected pillars 220 of the memory array 200 may be electrically floating when the transistor 225-a is activated, or may be coupled with another voltage source (e.g., grounded, via a high-resistance path, via a leakage path) to avoid a voltage drift of the pillars 220. For example, a ground voltage being applied to the gate line 210-a-3 may not activate other transistors coupled with the gate line 210-a-3, because the ground voltage of the gate line 210-a-3 may not be greater than the voltage of the other sense lines 215 (e.g., which may be biased with a ground voltage or may be floating). Further, other unselected gate lines 210, including gate line 210-a-5 as shown in FIG. 2B, may be biased with a voltage equal to or similar to an access bias (e.g., −Vaccess/2, or some other negative bias or bias relatively near the access bias voltage), such that transistors 225 along an unselected gate line 210 are not activated. Thus, the transistor 225-b coupled with the gate line 210-a-5 may be deactivated (e.g., operating in a non-conductive state), thereby isolating the voltage of the sense line 215-a-4 from the pillar 220-a-45, among other pillars 220.

In a write operation, a memory cell 202 may be written to by applying a write bias (e.g., where Vaccess=Vwrite, which may be a positive voltage or a negative voltage) across the memory cell 202. In some examples, a polarity of a write bias may influence (e.g., determine, set, program) a behavior or characteristic of the material of the memory cell 202, such as the threshold voltage of the material. For example, applying a write bias with a first polarity may set the material of the memory cell 202 with a first threshold voltage, which may be associated with storing a logic 0. Further, applying a write bias with a second polarity (e.g., opposite the first polarity) may set the material of the memory cell with a second threshold voltage, which may be associated with storing a logic 1. A difference between threshold voltages of the material of the memory cell 202 for different logic states stored by the material of the memory cell 202 (e.g., a difference between threshold voltages when the material is storing a logic state ‘0’ versus a logic state ‘1’) may correspond to the read window of the memory cell 202.

In a read operation, a memory cell 202 may be read from by applying a read bias (e.g., where Vaccess=Vread, which may be a positive voltage or a negative voltage) across the memory cell 202. In some examples, a logic state of the memory cell 202 may be evaluated based on whether the memory cell 202 thresholds in the presence of the applied read bias. For example, such a read bias may cause a memory cell 202 storing a first logic state (e.g., a logic 0) to threshold (e.g., permit a current flow, permit a current above a threshold current), and may not cause a memory cell 202 storing a second logic state (e.g., a logic 1) to threshold (e.g., may not permit a current flow, may permit a current below a threshold current).

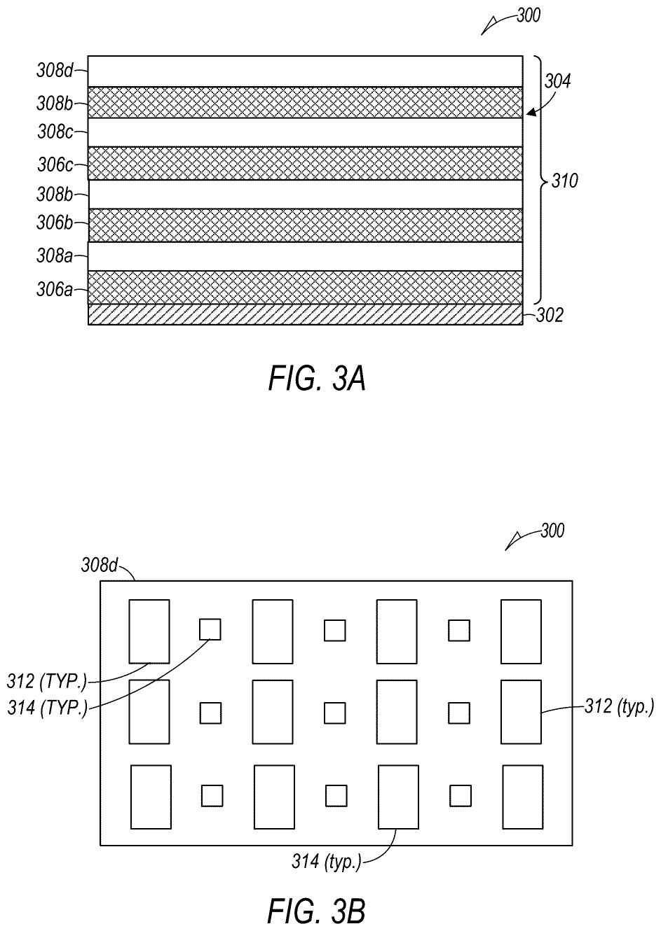

FIGS. 3A-3B depicts an example multi-tier memory structure 300 which may be formed and used as an initial structure from which the example structures of the remaining Figures are formed. Multi-tier memory structure 300 is formed on a substrate 302, which in many cases will be a semiconductor substrate, for example a silicon substrate. Though in some examples, substrate 302 may be formed of another material, for example a glass or ceramic material, which supports either directly or indirectly (through intervening materials) the semiconductor material tier. Multi-tier memory structure 300 includes an alternating stack structure forming the memory array portion 304 of the memory structure (after later processing), as described herein).

Structures used in forming the memory array portion 304 of memory structure 300 may be formed directly on the substrate 302 or above one or more levels of material extending over a surface of the substrate (not depicted). The memory array portion 304 (also termed herein, “memory array”), includes a stacked tier structure 310 which includes a stack of multiple alternating tiers of different material compositions. In many cases, a first set of dielectric tiers 306 (identified as 306a-306d) will include a first dielectric material to facilitate forming conductive structures alternating in between the dielectric tiers 306; as such the dielectric tiers may also be considered as spacer or separation tiers. In many examples the dielectric tiers 306 of the alternating tiers will comprise one or more oxides. Alternating with the dielectric tiers are the second set of tiers 308, termed herein “memory tiers,” as further described below. In the present example, these memory tiers 308 will initially include a placeholder material which may be selectively removed relative to the material of the first set of dielectric tiers 306.

For purposes of the present examples, construction of the memory array portion 304 will be accomplished through use of a technique broadly described as a “replacement gate” processing, in which various structures of the memory array will be constructed with the initial material of the second set of tiers 308 being a placeholder material. And at a later stage of processing, that placeholder material will be removed, at least in part, and replaced with a replacement gate material, commonly a metal or metal alloy, a significant portion of which will form word lines of the memory array. The memory tiers 308 will ultimately contain other materials forming bodies of memory cells, and thus for purposes of this illustration, for a convenient term to provide clarity of explanation, the second set of alternating tiers 308 between the tiers of dielectric material are termed in the present description “memory tiers,” addressing the location and ultimate function of the tier, regardless of whether that location is occupied by the initial placeholder material or by the later-placed replacement gate material.

The dielectric tiers 306 facilitate the memory cells being formed in contact with the dielectric tiers 306, which for intermediate memory tiers sandwich the memory tiers. For purposes of the present example, the dielectric tiers 306 will be described as formed of oxide. And in such examples, the initial placeholder material of the memory tiers 308 may commonly be a nitride of a composition selectively removable relative to the selected oxide of the tiers 306.

In the present examples, only a limited number of vertically alternating dielectric tiers 306 and memory tiers 308 are depicted, for clarity. Persons skilled in the art will recognize that a much greater number of such alternating tiers will typically be present in a commercial memory structure. For example, in various types of 3D memory structures, hundreds of memory tiers 308, and accompanying dielectric tiers 306, may be present. As persons skilled in the art will recognize, in some examples, memory tiers may be formed in vertically arranged groups (commonly termed “decks”) which interconnect to form the memory array.

Once the stacked tier structure 310 has been formed to a desired number of alternating memory tiers and dielectric tiers (as in FIG. 3A), openings will be formed in the tiers for forming, and for accommodating, other structures of the memory array. In the depicted example, multiple pier openings 312 have been formed extending through at least a portion of the stacked tier structure 310; and multiple pillar openings 314 have been formed extending through a respective portion of the stacked tier structure (which may in some examples be the same portion is that through which the pier openings 312 extend).

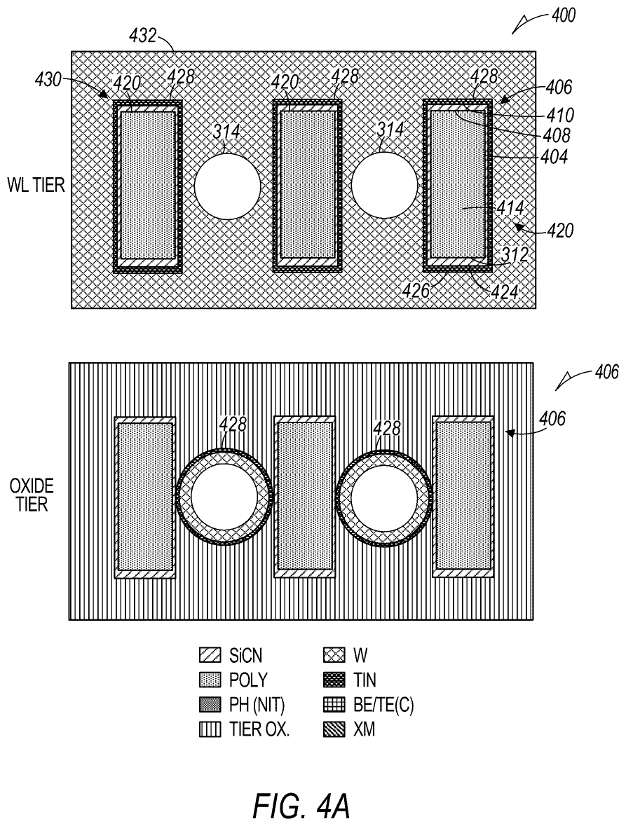

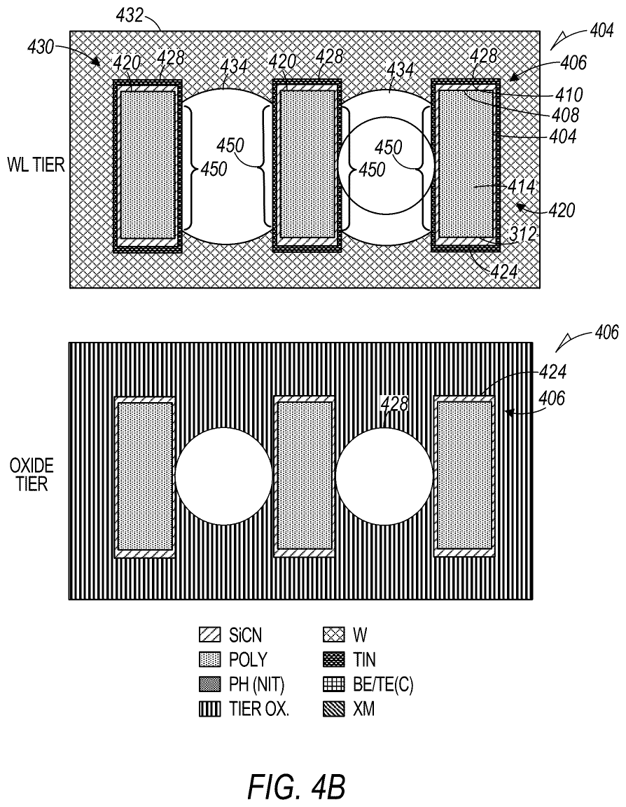

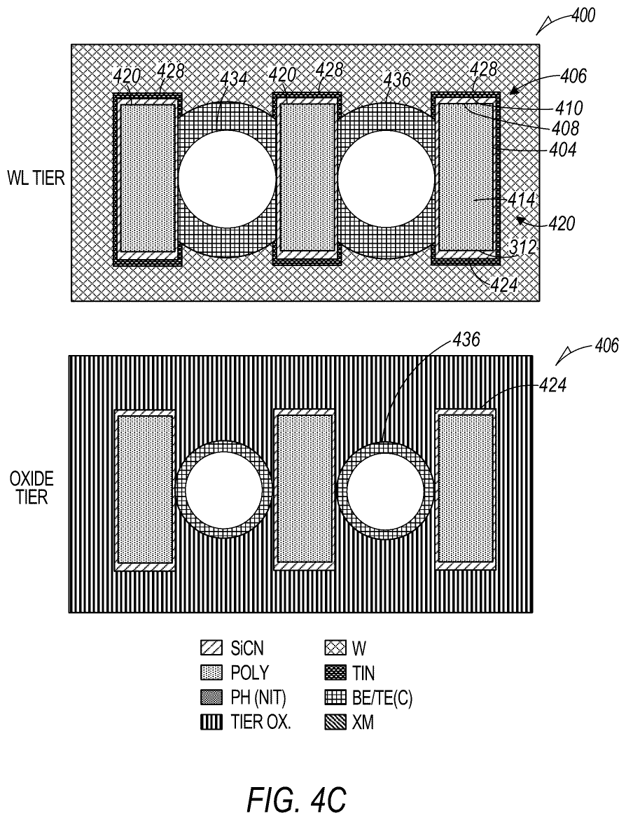

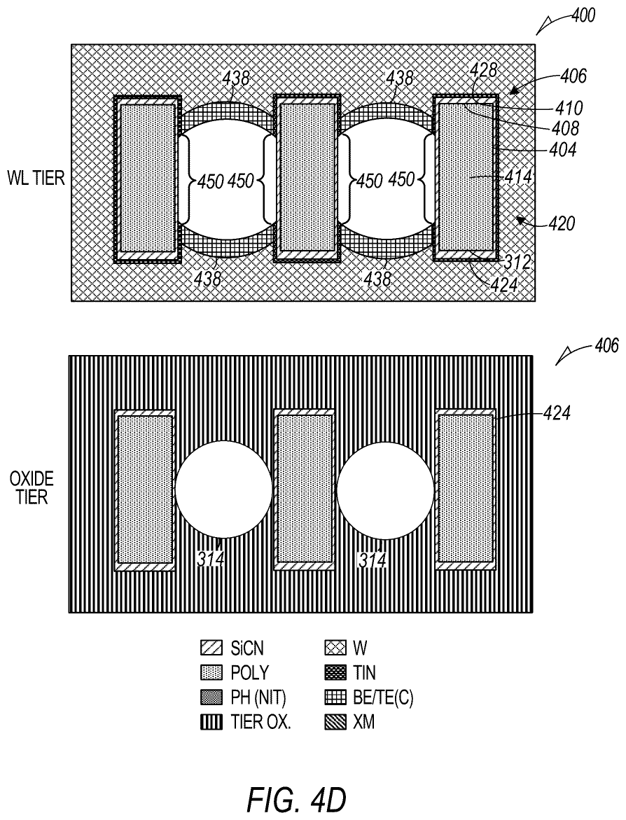

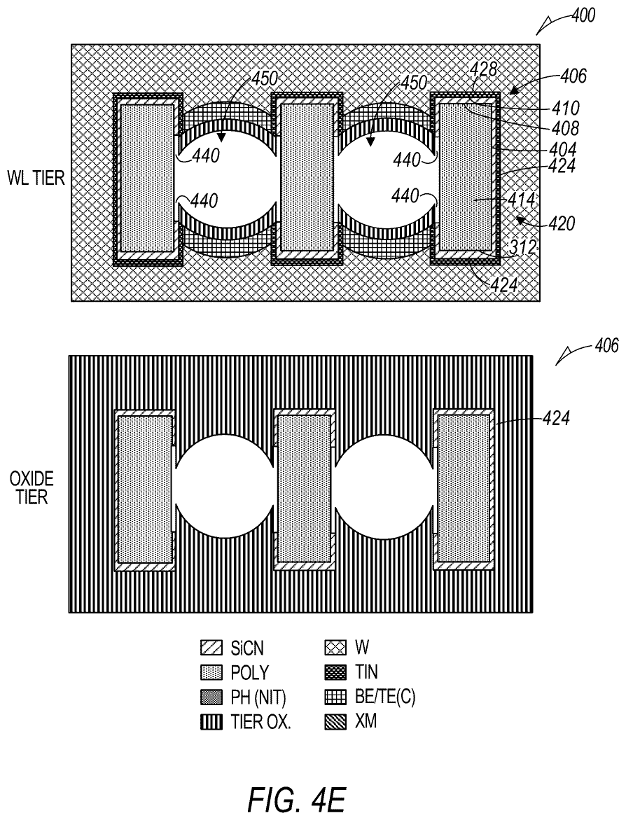

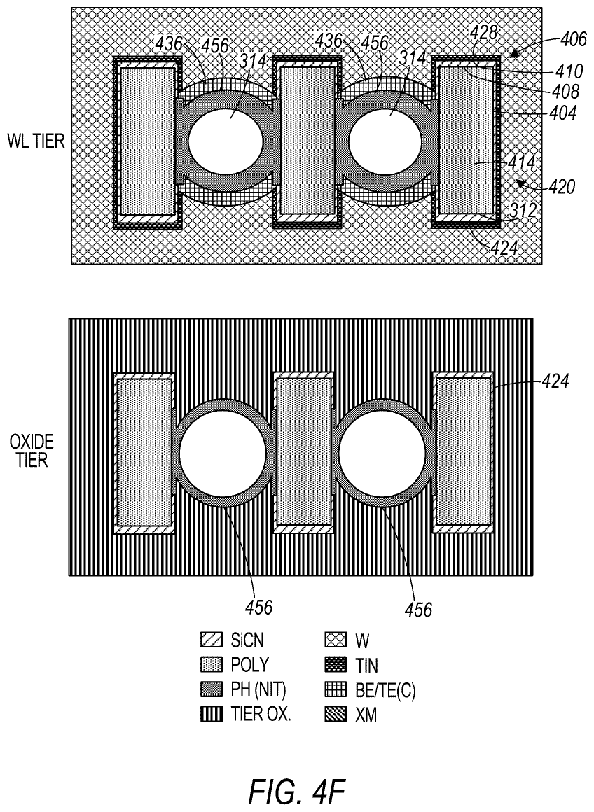

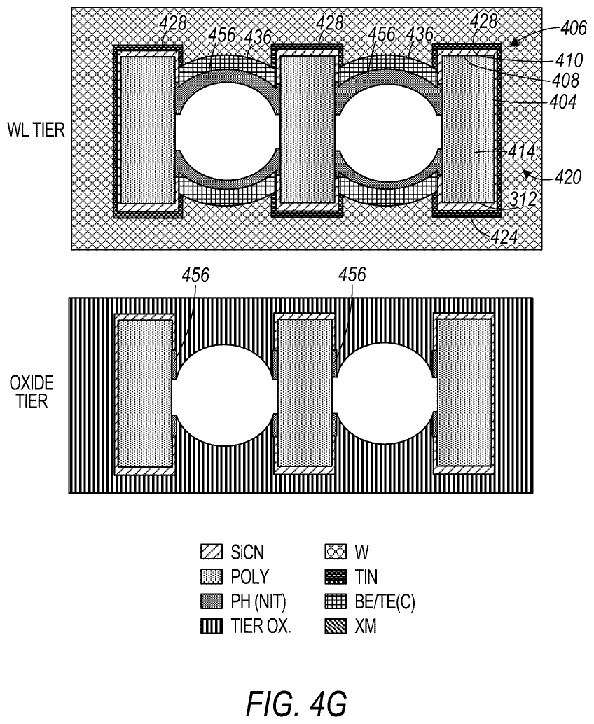

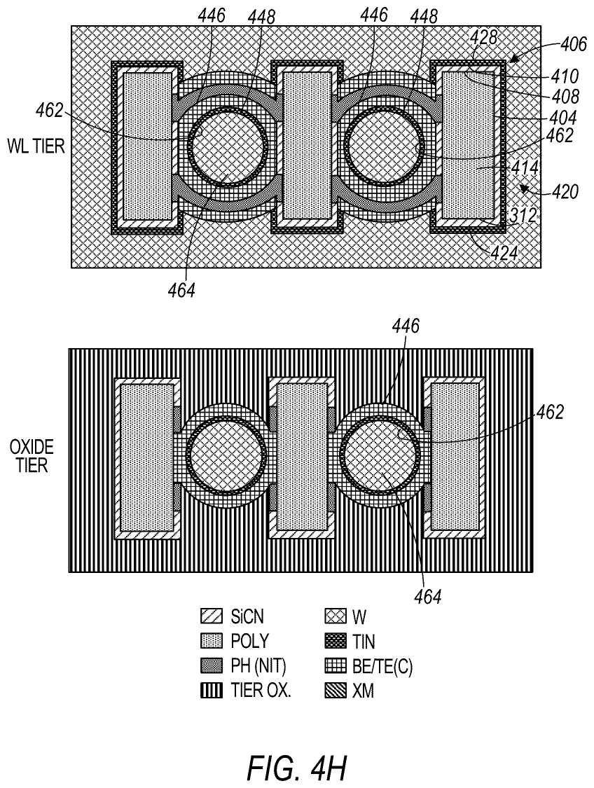

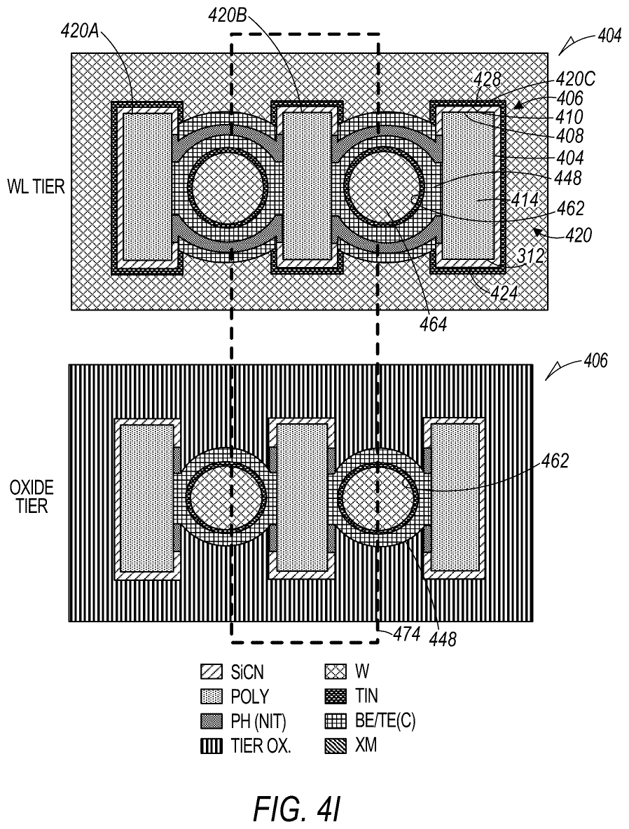

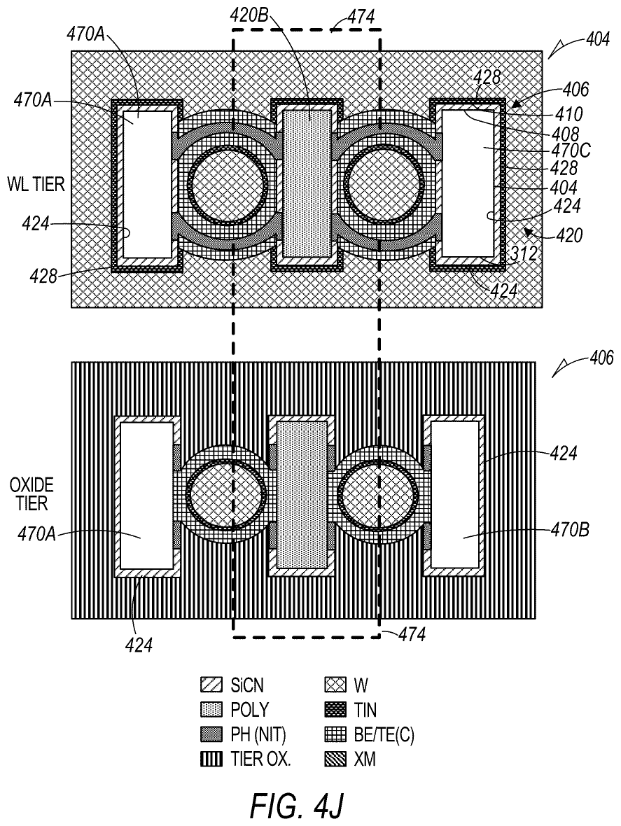

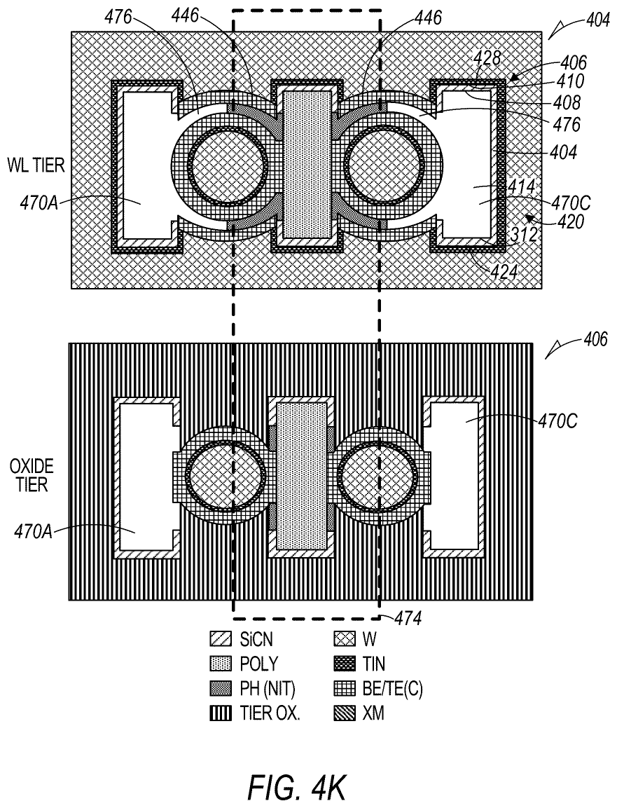

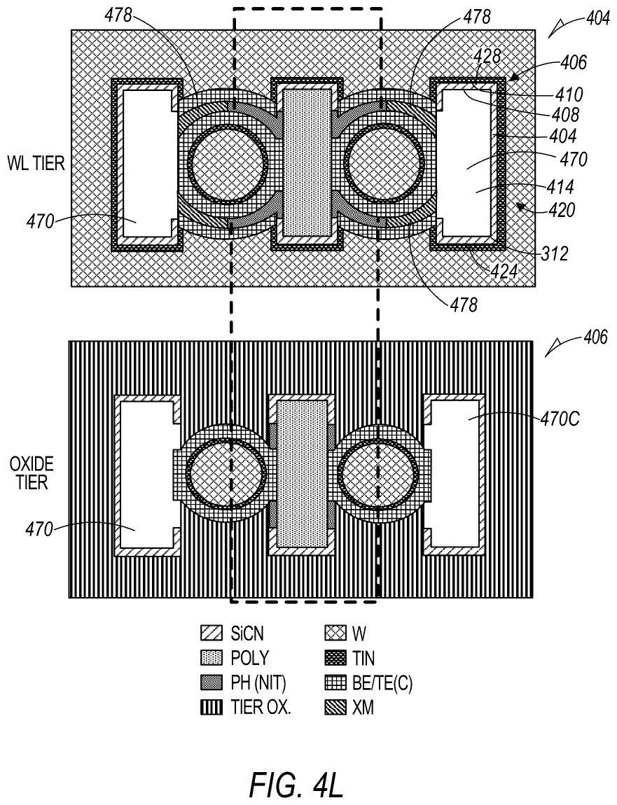

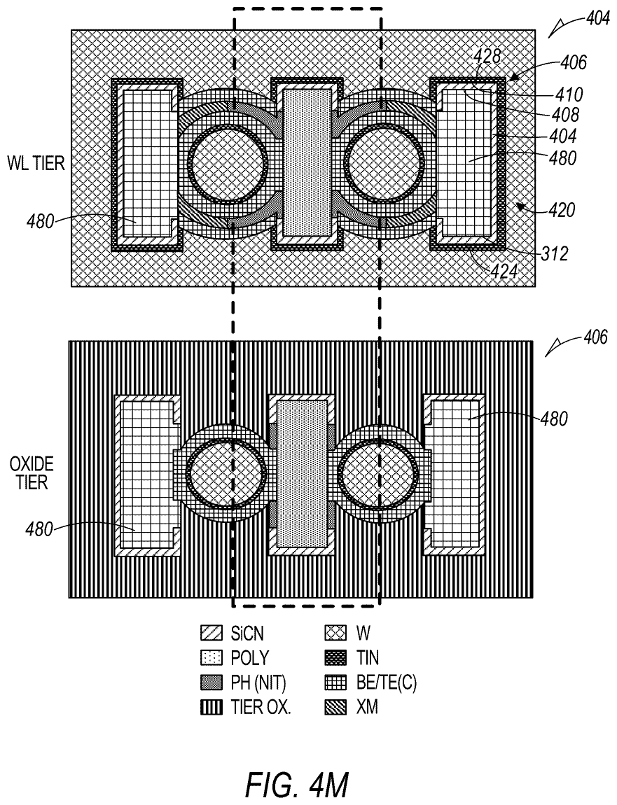

FIGS. 4A-4M depict example stages in an example process flow 400 for forming an example three-dimensional (“3D”) memory array, indicated generally at 402, through depiction of an example portion of a memory array (such as example memory array 200 of FIGS. 2A-2C) at various representative stages of an example manufacturing process flow. The stages of these Figures follow from the stacked tier structure 310 of FIG. 3A. The representative stages of each figure include two portions, an upper plan view of a representative memory tier (also termed herein a word line tier, abbreviated “WL Tier”), indicated generally at 404, and a lower plan view of a representative dielectric tier, indicated generally at 406, as will be vertically adjacent to at least one respective memory tier 404. For avoidance of doubt, the various stages of the process flow are represented by formation of memory cell structures to each side of a central pier, and extending to adjacent piers to each side of the central pier. Although not depicted in the representative stages, it should be understood that the same type of memory cell structures are also being formed on both sides of all piers aligned along the word line direction; and thus the same memory cell structures are being constructed beyond the outermost piers in the depiction of each stage. As depicted in FIG. 3A the initial stacked tier structure includes an alternating series of pier openings and pillar openings, and the pattern of memory cell formation similarly repeats along the word line direction.

For the avoidance of doubt, the term “adjacent” is used herein to identify structures or materials which are near to one another (within the dimensional scale of dimensions of structures, thickness of material layers, etc.), though not necessarily in physical contact with one another (as they may be separated by a material layer, for example). In the case of repeating structures that will be described, such as piers and pillars, which are in spaced relation to one another throughout the memory array, the term “adjacent” is used to identify that the two structures (piers, for example) are the neighboring structures (i.e., two piers are “adjacent” to one another along a first access, when there is no other pier along the first axis between the two piers along the first axis).

As depicted in FIG. 4A, the tiers are depicted at a replacement gate metallization stage. Relative to stacked tier structure 310 of FIG. 3A, the pier openings 312 have been filled with suitable pier fill material, indicated generally at 408, to form piers 420 in contact with the stacked structure surfaces defining pier openings 312. In the present example, the pier fill material 408 includes two materials: a first barrier material 410 forming a barrier layer 424 surrounding the surfaces defining the each of pier openings 312; and a primary pier material 414.

Barrier layer 424 may be formed as a generally conformal barrier or the first barrier material 410 may be deposited and etched back to form barrier layer 424. For purposes of the present example, barrier layer 424, may beneficially be, for example, a ceramic material, such as Silicon Carbon Nitride (SiCN). In the present example, the material barrier layer 424 will be selected to be able to withstand exhuming chemistry which will later be used to exhume primary pier material 414 from within pier openings 312. Other ceramics that may be used in barrier layer 424 include Aluminum Oxide (Al3O3), Tantalum Pentoxide (Ta2O5), and Zirconium Oxide (ZrO2); or other materials suitable for use in barrier layer 424 include polysilicon, amorphous silicon, silicon oxide, silicon nitride, silicon oxycarbide (SiOC) or lanthanum oxide (La2O3).

Primary pier material 414 will be a second material such as polysilicon or another readily removable material. In certain examples, the primary pier fill material 414 may be the same for all piers; however, in other examples, a first group of piers may have a first primary fill material such as that described above; while selected piers may have a different fill material, for example in response to placement of the selected piers proximate structures of the memory array to be formed later, in which cases the different fill material may be selected to facilitate later processing, such as potentially exhuming only alternate piers along the word line direction.

In the present example, after pier openings 312 are formed, and filled with pier fill material 408 forming piers 420, then pillar openings 314 are formed. Pillar openings 314 will ultimately contain respective conductive pillars serving as portions of bit lines of the memory array 402. As a result, in many examples, pillar openings 314 may commonly extend to intersect a respective conductive material structure formed beneath the stacked tier structure, but above the substrate, and forming a portion of respective memory array bitlines.

FIG. 4A further reflects additional processing, including, after exhuming at least a portion of the first placeholder material in the memory tiers 308 through use of the pillar openings 314. Exhuming of the first placeholder material will form voids defined by exposed dielectric material tier surfaces and first surfaces of the piers extending between the dielectric material tiers, those first surfaces comprising the first barrier layer material. As identified previously, the placeholder material 412 in the memory tiers 308 may be a nitride, in which case the nitride is exhumed, opening voids between the remaining structures and exposing surfaces of remaining structures. For example, surfaces of piers 420 extending between dielectric tiers 306 are exposed, while leaving the dielectric tiers and the supporting piers intact (with the exception of the previously formed pillar openings 314 extending through the dielectric tiers 306 of the stacked structure).

After at least a portion of the original placeholder material of the memory tiers 404 is exhumed, other material may be formed on the exposed portion of piers 420 extending through the vertical dimension of memory tiers 308. In the present example, conductive material, such as titanium nitride (TiN), indicated generally at 426, will be deposited through pillar openings 314 and etched back to a layer 428 extending over the ceramic (or other material) of barrier layer 424. In the completed memory array, titanium nitride layer 428 will serve as a liner to later-formed word lines (432). After formation of titanium nitride layer 428, the conductive word line material 430 deposited in the memory tier 404 and etched back to define the word lines 432 in memory tiers 404. In the present example, word line material 430 may be tungsten, or another material having comparable conductivity and mechanical properties.

FIG. 4B depicts the structure of FIG. 4A after etch back of the word line material 430 and titanium nitride layer 428 to form memory cell recesses 434 in which multiple memory cells will be formed. The etch back of the word line material 430 and titanium nitride layer 428 will remove a portion of the titanium nitride layer 428 in a region indicated generally at 450, adjacent the newly formed memory cell recesses 434, while leaving the barrier layer 424 intact between piers 420 and remaining word lines 432. This etch back also removes word line material 430 and titanium nitride 428 from oxide tiers 406. In the depicted example the cell recesses 434 are curvilinear in a horizontal plane (as viewed from above as in FIG. 4B); and later-formed structures within the recesses (such as first electrodes 436, placeholder material 456 and second electrodes 460, in later drawings) will similarly be curvilinear within that horizontal plane.

In the present example process flow, multiple variable resistance memory cells will be formed within memory cell units, in which the multiple memory cells have first electrodes in electrical communication with respective access lines, for example word lines; but the multiple memory cells have second electrodes in electrical communication with another access line, for example a bit line. In the present example, two memory cell units are formed on opposite sides of a central pier; and the two variable resistance memory cells of the example memory cell units are formed on, what will ultimately be, opposite sides of the conductive pillar of a bit line (in the example in a second direction orthogonal to the word line direction); though at the time of formation of the electrodes for the two variable resistance memory cells, the electrodes for each cell will be on opposite sides of a pillar opening. As further described further below, the second electrodes of the memory cells within a respective memory cell unit may be formed as a unitary structure.

Referring now to FIG. 4C, a first electrode material 436 is formed within memory cell recess 434 by deposition through pillar openings 314. First electrode material 436 will commonly be a material capable of providing good electrical contact with both material of the word lines 432 (in the present example, tungsten), and the chalcogenide or other material of the memory elements of the array. For purposes of the present example the first electrodes may be formed of carbon. As depicted in FIG. 4D, the first electrode material 436 is etched to a desired lateral dimension desired for the first electrodes 438 formed from first electrode material 436; which also results in removal of excess first electrode material 436 within oxide tier 406 (compare to FIG. 4C).

The described forming of first electrodes 438 also re-exposes portions of the barrier layer 424 in regions 450 on the recess-facing surfaces of piers 420. As depicted in FIG. 4E, the exposed portions 440 of barrier material 424 are recessed, taking care to not remove remaining surfaces of the word line liner, titanium nitride layer 428. In the present example construction that is accomplished by taking care to leave the interface between electrode 436 and barrier material 424 intact, shielding titanium nitride layer 428. For purposes of the present example, the recessing of exposed portions of barrier layer 424 in region 450 can be accomplished by several processes. In a first example, a remote plasma etch using fluorine radicals can be used to recess the SiCN barrier layer 424. Alternatively, an essentially atomic etch process may be utilized, wherein a surface of the SiCN layer is oxidized, and the oxidized surface is then removed through use of hydrogen fluoride (HF) vapor, which may proceed iteratively to complete the recessing.

Referring now to FIG. 4F, a placeholder material 456, for example, nitride, is deposited in the remaining portion of memory cell recess 434 adjacent first electrodes 438. And as depicted in FIG. 4G, the placeholder material 456 is recessed to a dimension that will be desired as a lateral dimension for the memory element that will be formed later, as the lateral thickness of the placeholder material will define the spacing between the first electrodes 438 and the second electrodes to be formed, and a lateral dimension of the memory element which will be formed within that spacing. Placeholder material 456 thereby forms a spacer for spacing the second electrode from the first electrode along the first axis and also provides a spacer that will constrain the dimension of the variable resistance element within (later-formed) recesses 476 between the first electrodes 438 and later-formed second electrodes 460. The recessing of placeholder material 456 will be accomplished with a process that will not attack the barrier layer 424 or the primary pier material 414.

Referring now to FIG. 4H, second electrode material 448 is deposited adjacent recessed placeholder material 446, and recessed, to form second electrodes 460. Subsequently, prior to forming conductive pillars (464) a conductive liner material 462, such as titanium nitride will be formed adjacent second electrodes 460, forming a conductive barrier layer. The conductive barrier layer 462 will be followed by forming a conductive pillar 464, such as again tungsten, formed within approximately the original dimension of pillar openings 316, to form the vertically extending portion of the array bit lines.

Referring now to FIGS. 4I-4M, the Figures depict forming the remainder of the memory cells in the memory tiers 404. Completion of the memory cells is accomplished by exhuming the outer piers (420A, 420C) of three generally adjacent piers 420A, 420B, 420C along the word line direction, while leaving the central pier 420B intact. For the avoidance of doubt, the terminology “adjacent” relative to the repeating structures of the piers across the horizontal dimensions of the memory array is meant to indicate that the three recited piers are consecutive with one another along the word line direction (i.e., along the word line direction the three piers are “adjacent” because there is no additional pier between any pair of the three tiers), with, of course, the additional described structures of the memory cells being disposed between pairs of the three piers.

The openings 470A, 470C resulting from the exhuming provide access to complete at least four memory cells generally adjacent the remaining pier 420B. The exhuming is performed through use of a hard mask 474 which will protect the central piers 420B within each group of three piers across the array, as the polysilicon of the two piers 420A, 420C is exhumed, resulting in the structure of FIG. 4J. As can be seen in the Figures, each resulting opening 470A, 470C after the exhuming is bounded by barrier layer 424 (in the example SiCN), which serves to protect remaining titanium nitride layer 428 from exposure to the exhuming process (i.e., the conditions and processing chemistry) and thus from potential resultant damage, maintaining its integrity as a word line liner as the piers 420A, 420C are exhumed, thereby further preventing possible damage to word lines 432. This benefit is achieved by maintaining multiple barrier materials between the pier material (and during processing, the pier openings) and a nearby portion of word lines extending near the pier (or pier opening). In the present example this result is achieved by maintaining at least a segment of each of two barrier materials (the pier barrier layer 424, and the titanium nitride word line liner 428), between a respective access line and the adjacent piers and/or pier openings.

Referring now to FIG. 4K, a portion of the placeholder material 446 (in the present example, a nitride) not covered by hard mask 474 is etched to define recesses 476 between first electrodes 438 and second electrodes 460 on both sides of remaining piers 420B. Subsequent, a chalcogenide material or other memory element material 478 will be placed in recesses 476 as shown in FIG. 4L. Finally, a placeholder material 480 will be deposited in the remaining portion of openings 470A, 470C, to complete the memory array structure, as depicted in FIG. 4M.

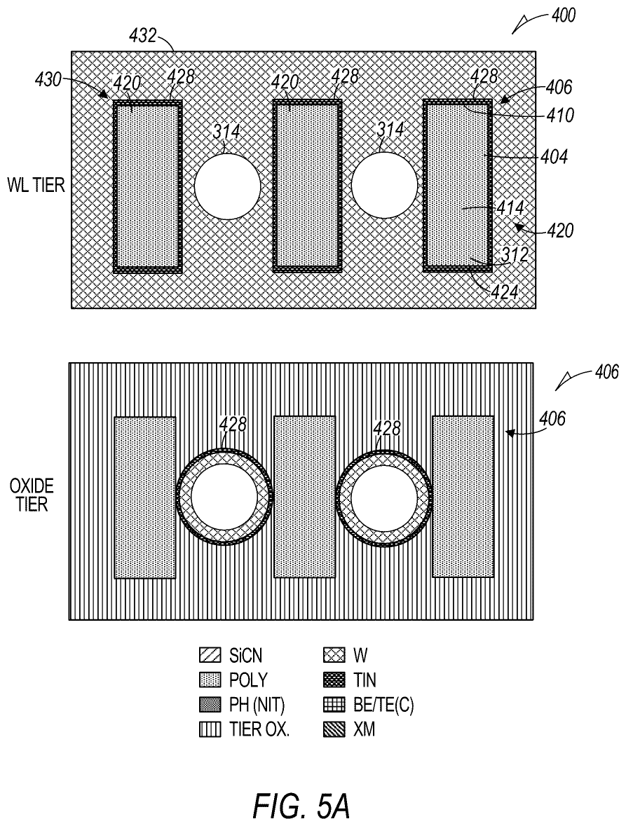

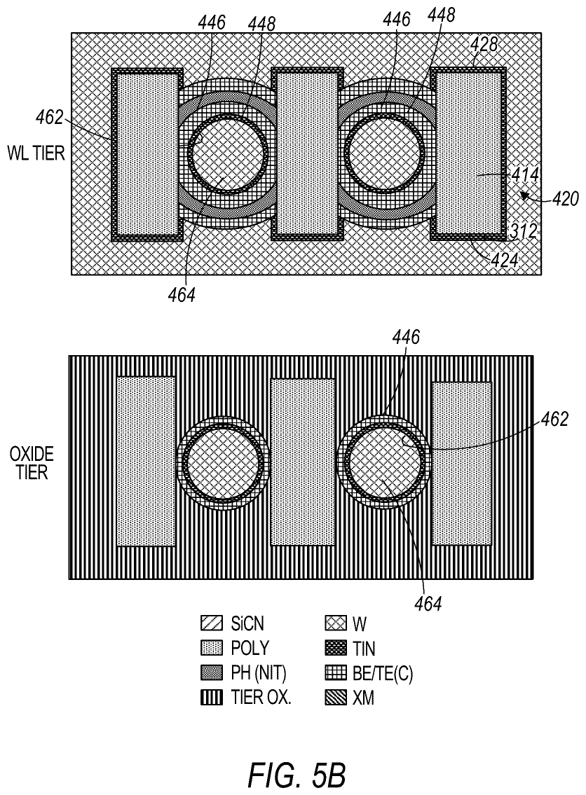

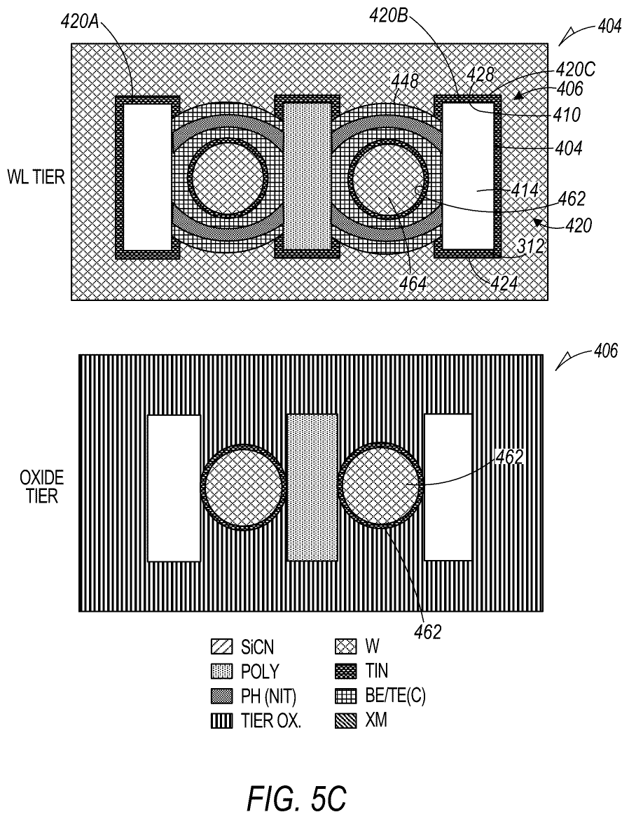

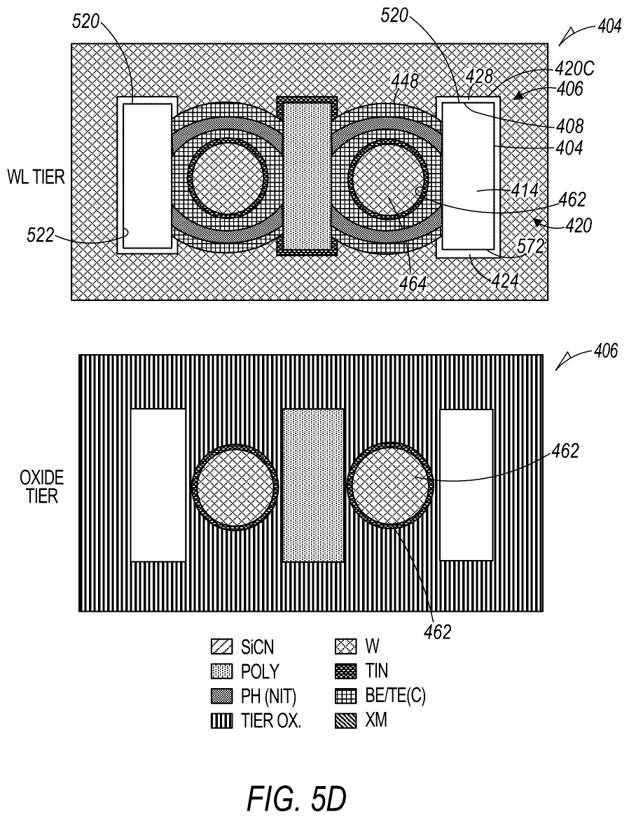

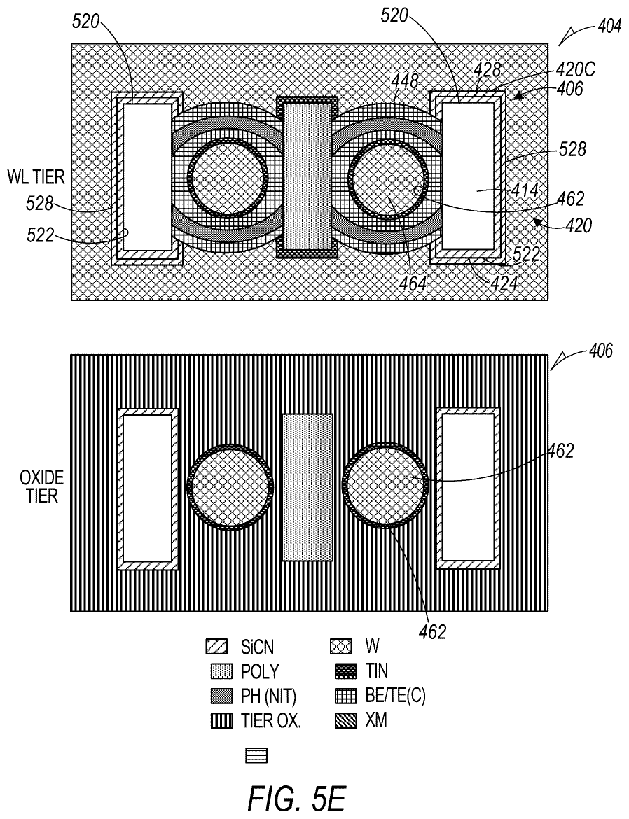

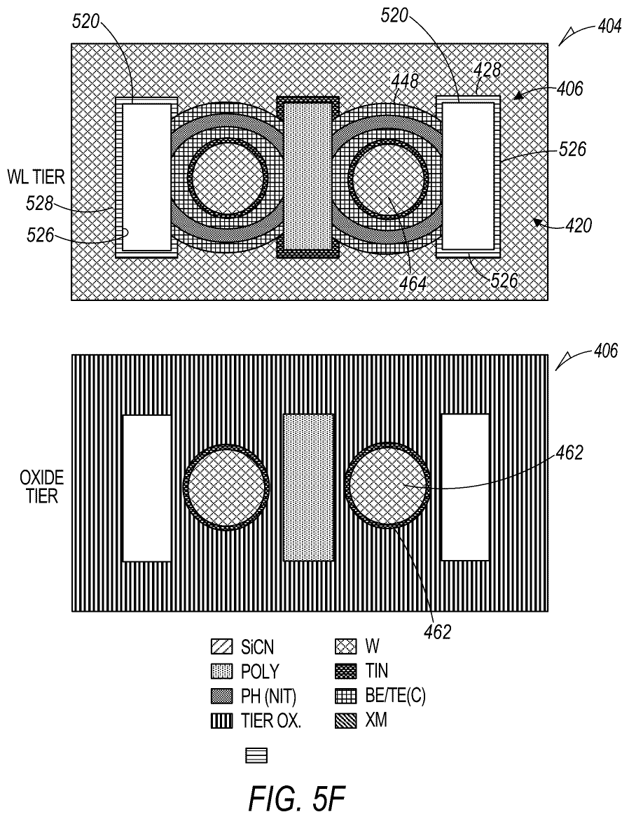

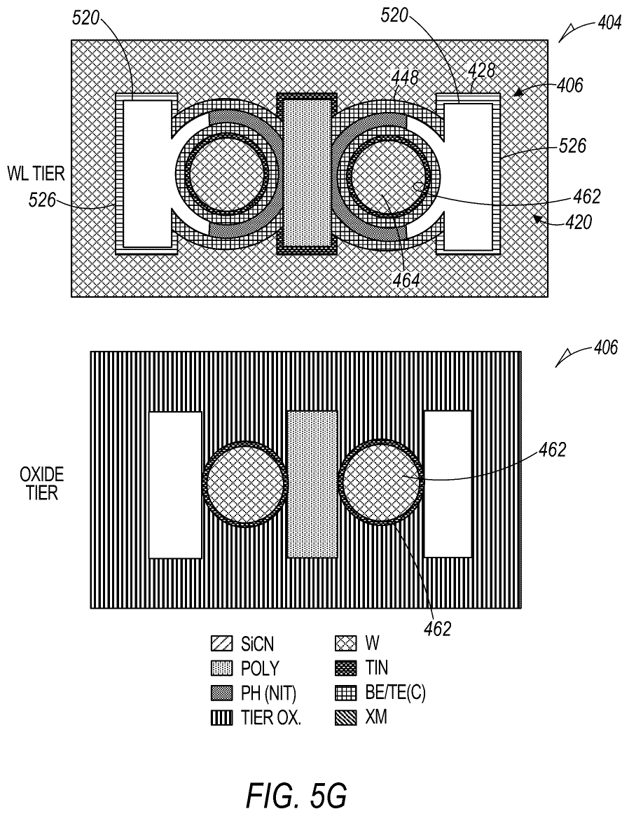

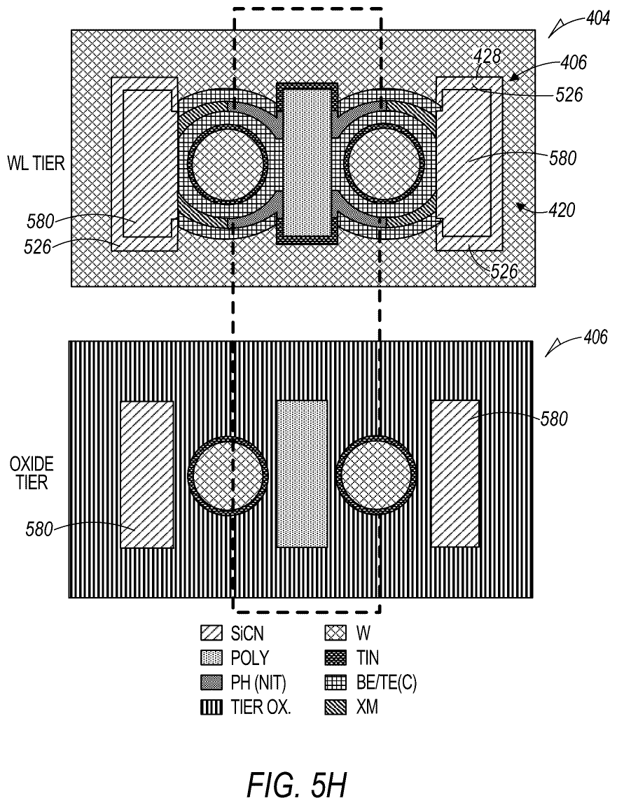

Referring now to FIGS. 5A-5G the Figures depict successive representative stages of another example process flow 500 for forming structures of a memory array, such as a cross-point memory array. Process flow 500 differs primarily in the stage of the process in which a barrier material is formed within the pier openings. As discussed above, after formation of some structures of the memory cells, piers will be exhumed from the pier openings in the multi-layer stack of layers to facilitate completing the memory cells, in the present example by depositing memory element material between the first and second electrodes of each memory cell. In the example of FIGS. 4A-4M, the barrier layer 424 is formed before replacement gate metallization, wherein the original placeholder material of the memory tiers is replaced, in the described example process, with a titanium nitride word line liner 428, followed by tungsten word lines. In process flow 400, that barrier layer 424 remains in place during pier exhumation as discussed relative to FIG. 4J, and through construction of the memory cells, and during refilling of the piers with placeholder material, all as described relative to FIGS. 4K-M.

In contrast, in the example of FIGS. 5A-5G, a titanium nitride layer is deposited as a portion of the replacement gate metallization (as it was in example process flow 400), but without a previously formed barrier layer (424) whining the pier openings. The formed titanium nitride layer extends both between the alternating dielectric tiers and the memory tiers, and also forms a liner for the piers. Further processing, generally analogous to that of processing flow 400, is performed after construction of the memory cells to the point at which the piers will be exhumed (as depicted in FIGS. 5B-5C). At that stage, the word line material will be recessed, expanding the dimension of the pier openings, and a barrier layer will then be formed within the expanded pier openings. That barrier layer will protect the word lines during recessing of the placeholder material between the electrodes, to define a recess which will receive the memory element material.

In addressing FIGS. 5A-5G, structures and materials that are directly comparable to structures and materials of process flow 400, will be identified with the same reference numerals, for ease of understanding. Additionally, as discussed relative to process flow 400, in the discussion of process flow 500, the various stages of the process flow are represented by formation of memory cell structures to each side of a central pier, and extending to adjacent piers to each side of the central pier; though not depicted in the representative stages, it again should be understood that the same type of memory cell structures are also being formed on both sides of all piers aligned along the word line direction; and thus the same memory cell structures are being instructed beyond the outermost piers in the depiction of each stage. And as discussed relative to I FIG. 3A the initial stacked tier structure includes an alternating series of pier openings and pillar openings, and the pattern of memory cell formation similarly repeats along the word line direction.

Referring now to FIG. 5A, the tiers are depicted at a replacement gate metallization stage. Relative to stacked tier structure 310 of FIG. 3A, the pier openings 312 have been filled with suitable pier fill material 414 to form piers 420 in contact with the stacked structure surfaces defining pier openings 312. Unlike in processing flow 400, the pier fill material 414 will includes only a single pier material, which in many examples may be polysilicon. Additionally, the structure is depicted after exhuming of the initial placeholder material of the word line (WL) tiers, and titanium nitride has been deposited in the voids left by the exhuming, thereby providing barrier layers between each memory tier and adjacent dielectric tiers (for example, oxide), and also on exposed surfaces of each pier formed by pier fill material 414 extending between the oxide tiers. Additionally, the initial placeholder material of the memory tiers has been replaced with word line material 430, which in the present example will be discussed as tungsten.

Referring now to FIG. 5B, processing flow 500 is at a stage directly analogous to that discussed relative to FIG. 4I, wherein a substantial portion of the memory cell structure has been formed. After recessing of the tungsten word line material 430 and the titanium nitride barrier layer 424, the partially concentric first electrodes 436, placeholder material 456, and second electrodes have been formed, all three extending between a respective relatively outer pier 420A, 420C and a central pier 420B. As a result, the processing flow is depicted immediately before exhuming of the pier fill material 414 of the piers 420A and 420C.

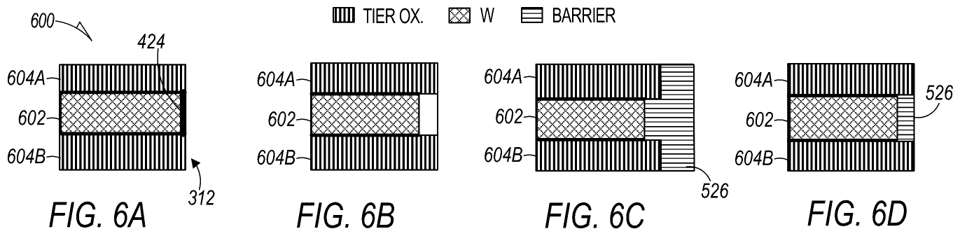

In FIG. 5C, outer piers 420A and 420C have been exhumed, leaving only titanium nitride barrier 424 in place around the perimeter of the pier openings 312. Referring also to FIG. 6A is a vertical cross-section representation of an example segment 600 of the stack structure, depicting a representative word line 602 extending between two dielectric tiers 604A, 604B, as can be seen in the Figure, titanium nitride barrier 424 extends horizontally between word line 602 and each adjacent dielectric tier 604A, 604B. Additionally, titanium nitride barrier 424 extends vertically at the perimeter of the pier openings 312.

Subsequently, as depicted in FIG. 5D the word line material (here, tungsten) surrounding the pier openings is recessed, at 520, to expand the pier openings beyond the original dimension indicated by line 522, which will also remove at least some portion, and in many examples, all of the titanium nitride barrier on vertical surfaces of the piers, as the material of word line 602 is recessed (as also depicted in the vertical cross-section representation of FIG. 6B).

Referring now to FIG. 5E, a barrier material 526 may be deposited within the expanded pier openings 528 (see also, cross-section of FIG. 6C); and as depicted in FIG. 5F barrier material 526 may be recessed to a desired dimension within expanded pier openings 528. For example, as depicted in the cross-section of FIG. 6D, barrier material 526 may be recessed to a vertical surface of the oxide tiers, with the tungsten and titanium nitride isolated from the pier openings by remaining barrier material 526. As the barrier material will be etched back to a desired dimension, it will have surfaces which define remaining pier cavities within the expanded pier openings (i.e., the pier cavities will be the remaining space within the expanded pier openings not occupied by the barrier material 526).

Referring now to FIG. 5G, barrier material 526 may be of various materials which will withstand processing chemistry and conditions that will be used to remove a portion of the (nitride) placeholder material 456 to form a recess 476 to receive memory element material (478 in FIG. 5H). Accordingly, barrier material 526 can be either a metal or dielectric, so long it is able to withstand the etch chemistries it will be exposed to in subsequent processing. In general, many etch processes and chemistries useful for etching the nitride placeholder material are similarly effective at etching tungsten. As a result, a significant function of barrier material 526 is to isolate the tungsten word lines from such etch processes and chemistries. An example such barrier material is Silicon Carbon Nitride (SiCN) as discussed previously regarding processing flow 400. Other potential materials include: polysilicon, amorphous silicon, silicon oxide, silicon nitride, silicon Oxycarbide (SiOC), aluminum oxide (Al2O3), hafnium oxide (HfO2), tantalum pentoxide (Ta2O5), zirconium oxide (ZrO2), lanthanum oxide (La2O3), or similar materials.

Once recess 476 has been formed, and memory element material 478 has been deposited within the recess and etched back to a desired dimension, the structures of the memory cells themselves are complete. At that point as depicted in FIG. 5H, the pier openings and any voids connected to the pier openings may be filled with a desired fill material. In some examples that may be polysilicon; or other materials, such as SiCN, may be used as a final fill material 480 to complete the memory array structure.

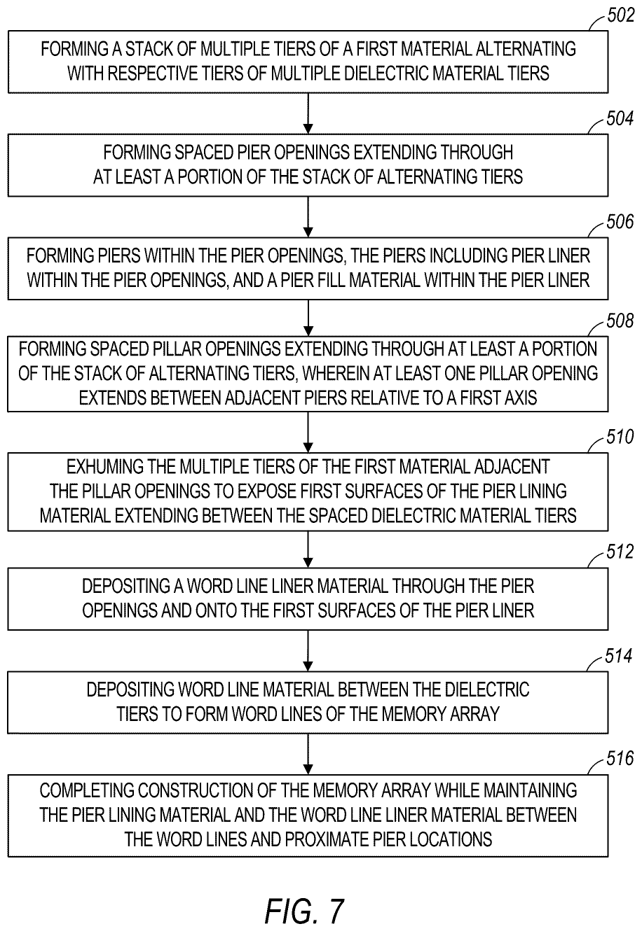

Referring now to FIG. 7, the figure depicts an example flow chart of a method 700 for constructing a 3D cross-point memory array having vertically extending piers and pillars extending through a stacked tier structure, and which may be implemented in a manner generic to the example processing flow 400 to form multiple material barriers protecting conductive structures, such as word lines, during processing operations.

Example method 700 begins with forming the stacked tier structure 702, wherein the stack includes multiple tiers of a first material (308 in FIG. 3A) alternating with respective tiers of multiple dielectric material tiers (306 in FIG. 3A) that will be used in forming a memory array, as described relative to FIGS. 3A and 3B. As described relative to such Figures, the stacked tiers 308, 306 may be formed over a substrate (304 in FIG. 3A), and potentially over multiple conductive and non-conductive materials located between the stacked tiers and the substrate. Subsequently, as indicated at 704, spaced pier openings (312 in FIG. 3B) will be formed extending through at least a portion of the stack of alternating tiers; and as indicated at 706, pier fill material 408 will be formed within the pier openings (312) to form vertically extending piers (420 in FIG. 4A). As described previously with respect to FIG. 4A the pier fill material 408 will include two materials, a pier liner material and a primary pier material. As described herein, in one example the pier liner material may be SiCN, and the primary pier material may be polysilicon.

Subsequently, as indicated at 708, spaced pillar openings (314 in FIG. 3B) will be formed extending through at least a portion of the stack of alternating tiers. In selected embodiments, such as the example embodiment described herein, the spaced pillar openings (314) may be located between adjacent piers (or pier openings) relative to a first axis.

As indicated at 710, the example method 700 includes exhuming the multiple tiers of the first material, either completely, or at least adjacent the pillar openings (314), first surfaces of the pier lining material extending between the dielectric material tiers. Subsequent, as indicated at 712, the method includes forming word line liner material on the exposed first surfaces of the pier lining material. As described above, the word line liner material may beneficially be titanium nitride. Additionally, example method 700 is not limited to a single barrier material, and multiple barrier materials may be deposited proximate one another and extending to the previously exposed first surfaces of the pier lining material.

As indicated in 714, the example method 700 includes depositing word line material in contact with the word line liner material. As a result, the first barrier material may be used to protect the word line liner, and word line, during subsequent operations in forming the memory array. Finally, as indicated at 716, the construction of the memory array will be completed with the portions of the word line liner contacting the word line material maintained intact through the remaining processing. As described above, a portion of the word line liner on the pier surface adjacent the first and second electrodes of a pair of memory cells may be removed, and with the entirety of the pier lining material remaining intact. Maintaining those two materials during further processing protects the word lines from damage, thereby improving reliability and performance of the completed memory device.

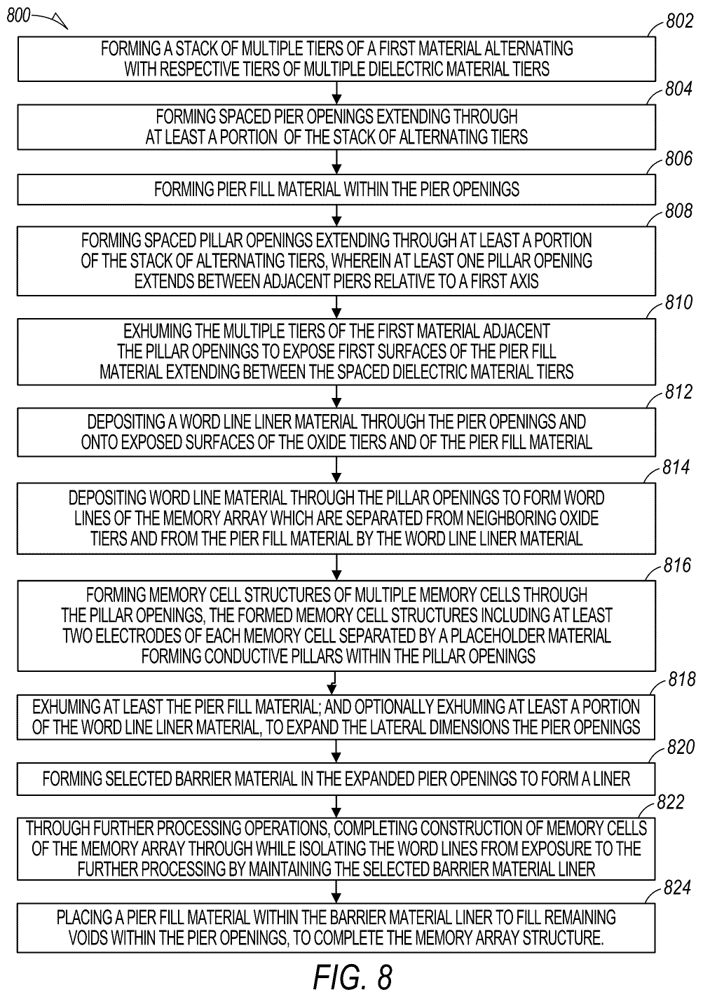

Referring now to FIG. 8, the figure depicts another example flow chart of a different method 800 for constructing a 3D cross-point memory array having vertically extending piers and pillars extending through a stacked tier structure, and which may be implemented in a manner generic to the example processing flow 500 to form material barriers protecting conductive structures, such as word lines, during processing operations.

Method 800, like method 700, begins with a stack of multiple tiers of a first material, such as a placeholder material, such as nitride, which alternate with respective tiers of multiple dielectric material tiers, which may be formed, as indicated in 802.

As indicated in 804 the method includes forming spaced pier openings extending through at least a portion of the stack of alternating tiers; as shown for example in FIG. 3A); and forming pier fill material within the pier openings as indicated at 806. As noted previously, this pier fill material will be sacrificial, and may, in some examples, be polysilicon.

Subsequently, as indicated 808 spaced pillar openings will be formed extending through at least a portion of the stack of alternating tiers read at least one pillar opening extends between adjacent piers relative to a first axis. As noted previously this repeating pattern of piers and pillars alternating with one another along a first direction; such as in the present example along the word line direction, is depicted in the example of FIG. 3A.

As indicated at 810, the pillar openings will be used to facilitate exhuming the multiple tiers of the first material (adjacent the respective pillar openings) to expose first surfaces of the pier fill material extending between the spaced dielectric material tiers. Also as discussed previously, the exhuming of the first material will also expose surfaces of the dielectric tiers. Accordingly, and as indicated at 812, a word line liner material will be deposited through the pillar openings and onto the exposed surfaces of the dielectric tiers (for example, oxide tiers) as well as the exposed surfaces of the pier fill material. As will be apparent to persons skilled in the art the forming of the word line liner material will typically include a deposition, followed by an etch back to a desired dimension.

Subsequently, as indicated at 814, word lines will be formed between the dielectric tiers, such as by depositing word line material through the pillar openings to form the word lines which are separated from neighboring oxide tiers and from the pier fill material by the word line liner material.

Further, as indicated at 816, memory cell structures of multiple memory cells will be formed at least in part through the pillar openings. As indicated by the example processes described herein, the memory cell structures may include at least two electrodes separated from one another by a placeholder material, with at least one electrode of each memory cell in electrical communication with a conductive pillar formed within the pillar openings. As described above in example embodiment of these conductive pillars will extend vertically will form portions of bit lines of the memory array.

As indicated at 818, completion of forming the memory cells would be facilitated by exhuming at least the pier fill material of the piers, and potentially also exhuming all or a part of the word line liner material from the pier openings, to facilitate recessing the word line material to expand the lateral dimensions of the pier openings, at least in the memory tiers. As indicated at 820, the method further includes forming a selected barrier material in the expanded pier openings to form a barrier to protect the word line material during completion of the memory cells, as described further relative to FIGS. 5D-H.

As indicated at 822, the further processing may be performed to complete constructions of the memory cells, with the word lines isolated and protected from exposure to the further processing by maintaining the selected barrier material in place. As described for example, relative to processing flow 500, the further processing may include recessing the nitride placeholder 456, to form a recess for receiving deposited memory element material, which may then be recessed to complete the memory cell structure. Subsequently, a further pier fill material may be used to fill remaining voids and connected to the pier openings, to complete the memory array structure.

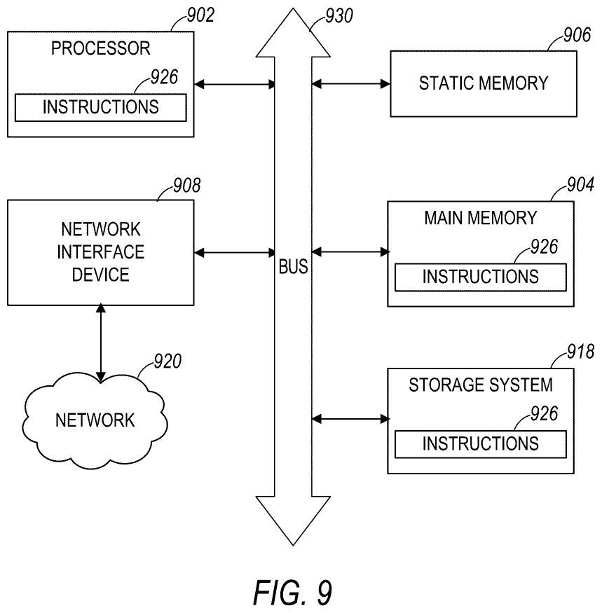

FIG. 9 illustrates a block diagram of an example electronic machine (e.g., a host system) 900 which may include one or more memory devices and/or systems as described above. A cross-point memory structure as previously described herein may be implemented as a discrete memory device, as a portion of a multi-chip device, or as a memory array formed on a device with other logic. For example, the cross-point memory structure as described herein could be implemented as first-tier cache memory or as a buffer available to a processor, and could potentially be formed on a common substrate with processing circuitry. The described cross-point memory structure may be used for any memory application within electronic machine 900. Machine 900 may benefit from enhanced memory reliability and/or performance from use of one or more of the described memory devices and/or memory systems, facilitating improved performance of machine 900 (as for many such machines or systems, efficient reading and writing of memory can facilitate improved performance of a processor or other components that machine, as described further below).

In alternative embodiments, the machine 900 may operate as a standalone device or may be connected (e.g., networked) to other machines. In a networked deployment, the machine 900 may operate in the capacity of a server machine, a client machine, or both in server-client network environments. In an example, the machine 900 may act as a peer machine in peer-to-peer (P2P) (or other distributed) network environment. The machine 900 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (Saas), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine (e.g., computer system, a host system, etc.) 900 may include a processing device 902 (e.g., a hardware processor, a central processing unit (CPU), a graphics processing unit (GPU), a hardware processor core, or any combination thereof, etc.), a main memory 904 (e.g., read-only memory (ROM), dynamic random-access memory (DRAM) such as synchronous DRAM (SDRAM) or Rambus DRAM (RDRAM), etc.), a static memory 906 (e.g., static random-access memory (SRAM), etc.), and a storage system 918, some or all of which may communicate with each other via a communication interface (e.g., a bus) 930. In one example, the main memory 904 or the storage system 918 may include one or more memory devices as described in examples above.

The processing device 902 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 902 can also be one or more special-purpose processing devices such as an application specific integrated circuit (ASIC), a field programmable gate array (FPGA), a digital signal processor (DSP), network processor, or the like. The processing device 902 can be configured to execute instructions 926 for performing the operations and steps discussed herein. The processing device 902 can further include a network interface device 908 to communicate over a network 920.

The storage system 918 can include a machine-readable storage medium (also known as a computer-readable medium) on which is stored one or more sets of instructions 926 or software embodying any one or more of the methodologies or functions described herein. The instructions 926 can also reside, completely or at least partially, within the main memory 904 or within the processing device 902 during execution thereof by the computer system 900, the main memory 904 and the processing device 902 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with multiple particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 900 may further include a display unit, an alphanumeric input device (e.g., a keyboard), and a user interface (UI) navigation device (e.g., a mouse). In an example, one or more display units, the input device, or the UI navigation device may be a touch screen display. The machine a signal generation device (e.g., a speaker), or one or more sensors, such as a global positioning system (GPS) sensor, compass, accelerometer, or one or more other sensor. The machine 900 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 926 (e.g., software, programs, an operating system (OS), etc.) or other data are stored on the storage system 918 can be accessed by the main memory 904 for use by the processing device 902. The main memory 904 (e.g., DRAM) is typically fast, but volatile, and thus a different type of storage than the storage system 918 (e.g., an SSD), which is suitable for long-term storage, including while in an “off” condition. The instructions 926 or data in use by a user or the machine 900 are typically loaded in the main memory 904 for use by the processing device 902. When the main memory 904 is full, virtual space from the storage system 918 can be allocated to supplement the main memory 904; however, because the storage system 918 device is typically slower than the main memory 904, and write speeds are typically at least twice as slow as read speeds, use of virtual memory can greatly reduce user experience due to storage system latency (in contrast to the main memory 904, e.g., DRAM). Further, use of the storage system 918 for virtual memory can greatly reduce the usable lifespan of the storage system 918.

The instructions 924 may further be transmitted or received over a network 920 using a transmission medium via the network interface device 908 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.9 family of standards known as Wi-Fi®, IEEE 802.16 family of standards known as WiMax®), IEEE 802.15.4 family of standards, pier-to-pier (P2P) networks, among others. In an example, the network interface device 908 may include one or more physical jacks (e.g., Ethernet, coaxial, or phone jacks) or one or more antennas to connect to the network 920. In an example, the network interface device 908 may include multiple antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 900, and includes digital or analog communications signals or other intangible medium to facilitate communication of such software.

The above Detailed Description includes references to the accompanying drawings, which form a part of the Detailed Description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” (in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” and “substrate” are used herein to refer generally to any structure on which integrated circuits are formed, and also to such structures during various stages of integrated circuit fabrication. The following Detailed Description is, therefore, not to be taken in a limiting sense, and the scope of the various embodiments is defined only by the appended claims, along with the full scope of equivalents to which such claims are entitled.

Various embodiments according to the present disclosure and described herein include memory utilizing a vertical structure of memory cells. As used herein, directional adjectives will be taken relative a surface of a substrate upon which the memory cells are formed (i.e., a vertical structure will be taken as extending away from the substrate surface, a bottom end of the vertical structure will be taken as the end nearest the substrate surface and a top end of the vertical structure will be taken as the end farthest from the substrate surface).

As used herein, directional adjectives, such as horizontal, vertical, normal, parallel, perpendicular, etc., can refer to relative orientations, and are not intended to require strict adherence to specific geometric properties, unless otherwise noted. For example, as used herein, a vertical structure need not be strictly perpendicular to a surface of a substrate, but may instead be generally perpendicular to the surface of the substrate, and may form an acute angle with the surface of the substrate (e.g., between 60 and 120 degrees, etc.).

Operating a memory cell, as used herein, includes reading from, writing to, or erasing the memory cell. The operation of placing a memory cell in an intended state is referred to herein as “programming,” and can include both writing to or erasing from the memory cell (i.e., the memory cell may be programmed to an erased state).

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

To better illustrate the method and apparatuses disclosed herein, a non-limiting list of examples is provided:

Example 1 is a method of forming a memory structure, comprising: forming a stack of multiple tiers of a first placeholder material alternating with respective tiers of multiple dielectric material tiers; forming spaced pier openings extending through at least a portion of the stack of multiple alternating tiers; forming a first barrier layer on surfaces of the stacked tiers defining the pier openings; depositing pier fill material in the pier openings with the first barrier layer surrounding the pier fill material to form piers; forming spaced pillar openings extending through at least a portion of the stack of multiple alternating tiers, wherein at least one pillar opening is located between adjacent piers relative to a first axis; exhuming at least a portion of the first placeholder material of the multiple tiers to form first voids defined by exposed dielectric material tier surfaces and first surfaces of the piers extending between the dielectric material tiers, the first surfaces comprising the first barrier layer; forming a second barrier material on the first surfaces of the piers to serve as a word line liner in the memory structure; and depositing word line material in contact with the second layer.

In Example 2, the subject matter of Example 1 wherein the first barrier layer includes a ceramic material.

In Example 3, the subject matter of Example 2 wherein the ceramic material is Silicon Carbon Nitride (SiCN).

In Example 4, the subject matter of any one or more of Examples 2-3 optionally includes wherein the second barrier material comprises nitride.

In Example 5, the subject matter of any one or more of Examples 2-4 wherein the second barrier material comprises one or more of Silicon Carbon Nitride (SiCN), Aluminum Oxide (Al3O3), Tantalum Pentoxide (Ta2O5), and Zirconium Oxide (ZrO2)).

In Example 6, the subject matter of any one or more of Examples 1-5 optionally include recessing the second barrier material and the word line material to define the word lines.

In Example 7, the subject matter of Example 6 wherein the second barrier material is recessed before depositing the word line material, and the wherein the word line material is isolated from the pier fill material by at least the first barrier layer.

In Example 8, the subject matter of Example 7 wherein both the second barrier material and the word line material are deposited, and then subsequently recessed, and wherein the word line material is isolated from the pier fill material by both the first barrier layer and the second barrier material.

In Example 9, the subject matter of any one or more of Examples 6-8 optionally include through use of an exhuming process, exhuming the pier fill material from outer piers of three adjacent piers along a first direction, leaving a central pier intact, wherein the first barrier layers adjacent the pier fill material of each of the outer piers limit exposure of the word lines and the second barrier material to the exhuming process; forming memory cell units on opposite sides of the central pier along the first direction, each memory cell unit comprising at least two variable resistance memory cells on opposite sides of a pillar opening along a second direction, wherein each variable resistance memory cell comprises a first electrode, a variable resistance material, and a second electrode; and forming conductive pillars in respective pillar openings, the conductive pillars forming portions of bit lines of the memory structure; wherein the first electrodes are in electrical communication with respective word lines; and wherein the second electrodes of the memory cells in a memory cell unit are each in electrical communication with respective conductive pillars.

In Example 10, the subject matter of Example 9 wherein the second electrodes of memory cells in a memory cell unit are integral with one another.

In Example 11, the subject matter of any one or more of Examples 9-10 wherein the variable resistance material of each memory cell is constrained in the first direction by at least one spacer, and in a second direction between the first and second electrodes.

In Example 12, the subject matter of any one or more of Examples 6-11 optionally include forming multiple memory cell units comprising: forming first electrodes in electrical contact with respective word lines, and extending horizontally between surfaces of the first barrier material on adjacent piers; forming a second placeholder material in physical contact with the first electrodes; forming second electrodes of each memory cell in physical contact with the second placeholder material and extending generally horizontally between surfaces of the first barrier layer.

In Example 13, the subject matter of Example 12 optionally includes forming conductive pillars extending within respective pillar openings, the conductive pillars in electrical communication with the second electrodes.

In Example 14, the subject matter of Example 13 optionally includes forming a conductive barrier layer on the second electrodes prior to forming the conductive pillars, wherein the conductive barrier layer extends between the second electrodes and respective pillars.

In Example 15, the subject matter of Example 14 wherein the conductive barrier layer comprises titanium nitride.

In Example 16, the subject matter of any one or more of Examples 12-15 wherein prior to forming the multiple memory cell units, the pillar openings in the memory tiers are etched to form cell recesses to accommodate the memory cell units to be formed.

In Example 17, the subject matter of Example 16 wherein the cell recesses are curvilinear in a horizontal plane, and where the first electrodes and the second electrodes are also curvilinear in the horizontal plane.

Example 18 is a method of forming a memory array, comprising: a stack of multiple tiers of a first placeholder material alternating with respective tiers of multiple dielectric material tiers; forming spaced pier openings extending through at least a portion of the stack of alternating tiers; forming a first barrier material on surfaces of the stacked tiers defining the pier openings; depositing pier fill material in the pier openings with the first barrier material surrounding the pier fill material to form piers; forming spaced pillar openings extending through at least a portion of the stack of alternating tiers, wherein at least one pillar opening is located between adjacent piers along a first generally horizontal direction; exhuming at least a portion of the first placeholder material of the multiple tiers to form openings for receiving access line material, the access line material extending in the first direction, the wherein the openings are defined in part by exposed first surfaces of the piers extending between the dielectric material tiers, the first surfaces comprising the first barrier material; forming a second barrier material on the first surfaces of the piers to serve as first access line liner material in a memory array; depositing first access line material in contact with the second barrier material; etching the pillar openings in the memory tiers to form cell recesses to accommodate forming multiple memory cell units in each memory tier, each memory cell unit comprising at least two variable resistance memory cells on opposite sides of a pillar opening in a second direction, wherein each variable resistance memory cell comprises a first electrode, a variable resistance material, and a second electrode; forming the variable resistance memory cells in the cell recesses, comprising, forming first electrodes in electrical contact with respective first access lines, the first electrodes extending horizontally between surfaces of the first barrier material on adjacent piers; forming a second placeholder material in physical contact with the first electrodes; forming second electrodes of each memory cell in physical contact with the second placeholder material and extending generally horizontally between surfaces of the first barrier material, wherein the second electrodes of at least two memory cells within a respective memory cell unit are formed as a single conductive electrode; forming conductive pillars within the pillar openings, the conductive pillars in electrical contact with the second electrodes of at least two memory cells within a respective memory cell unit; through use of an exhuming process, exhuming the pier fill material from outer piers of three adjacent piers along the first direction, leaving a central pier of the three adjacent piers intact, wherein the first barrier material adjacent the pier fill material of each of the outer piers limits exposure of the access lines and access line liners to the exhuming process; recessing the second placeholder material in the memory cells to define recesses defined at least in part by the respective first electrodes and second electrodes; depositing variable resistance memory material into the recesses, the variable resistance memory material in electrical contact with the respective first electrodes and second electrodes; and forming a third placeholder material in place of previously exhumed pier fill material of the outer piers of the three adjacent piers.

Example 19 is a memory array, comprising: a stack of spaced memory tiers, respectively containing multiple cross-point memory cells, and alternating dielectric tiers between the memory tiers; multiple word lines which extend to respective first pluralities of memory cells in a respective memory tier; and multiple bit lines which extend at least in part generally vertically and extend to respective second pluralities of memory cells distributed across multiple memory tiers; wherein the stack of memory tiers and dielectric tiers includes piers which extend through multiple memory tiers and dielectric tiers, and which are separated from contact with respective word lines by at least a first barrier material between the piers and respective word lines.

In Example 20, the subject matter of Example 19 optionally includes a word line liner material also extending between the first barrier material and the respective word lines.

In Example 21, the subject matter of any one or more of Examples 19-20 wherein the first barrier material partially surrounds the respective piers and extends vertically through the stack of spaced memory tiers and dielectric tiers.

In Example 22, the subject matter of any one or more of Examples 19-21 wherein the first barrier material comprises a ceramic material.

In Example 23, the subject matter of Example 22 wherein the first barrier material comprises Silicon Carbon Nitride (SiCN).

In Example 24, the subject matter of any one or more of Examples 19-23 wherein the first barrier material comprises one or more of Silicon Oxycarbide (SiOC), Aluminum Oxide (Al3O3), Tantalum Pentoxide (Ta2O5), and Zirconium Oxide (ZrO2)).

In Example 25, the subject matter of any one or more of Examples 20-24 wherein the second barrier material comprises nitride.

In Example 26, the subject matter of any one or more of Examples 20-25 wherein the word line liner material also extends horizontally between the word lines and the dielectric tiers.

Example 27 is a method of forming a memory array, comprising: forming an alternating stack of multiple tiers comprising first tiers of a first material alternating with second tiers of dielectric material; forming spaced pier openings extending through the stack of alternating tiers; forming pier fill material within the pier openings; forming spaced pillar openings extending through the stack of alternating tiers, wherein at least one pillar opening extends between adjacent piers relative to a first axis extending in a first direction; exhuming the multiple tiers of the first material through use of pillar openings to expose first surfaces of the pier fill material extending between the spaced dielectric material tiers; depositing a word line liner material through the pier openings and onto exposed surfaces of the dielectric tiers and of the pier fill material; depositing word line material through the pillar openings to form word lines of the memory array which are separated from adjacent oxide tiers and from the pier fill material by the word line liner material; forming memory cell structures of multiple memory cells through the pillar openings, the formed memory cell structures including at least two electrodes of each memory cell separated from one another by a placeholder material; forming conductive pillars within the pillar openings; exhuming at least the pier fill material to expand lateral dimensions of the pier openings to form expanded pier openings; forming selected barrier material in the expanded pier openings to form a liner; through further processing operations, completing construction of memory cells of the memory array through the expanded pier openings while isolating the word lines from exposure to the further processing by maintaining the selected barrier material liner; placing a pier fill material within the barrier material liner to fill the pier openings to complete the memory array structure.

In Example 28, the subject matter of Example 27 wherein forming the expanded pier openings further comprises exhuming at least a portion of the word line liner material to form the expanded pier openings.

In Example 29, the subject matter of any one or more of Examples 27-28 wherein forming the expanded pier openings further comprises exhuming the word line liner material previously contacting the piers.

Example 30 is a method of forming a memory array, comprising: forming multiple memory tiers within a stack of tiers, wherein each memory tier is separated from a vertically adjacent memory tier by a dielectric tier, wherein each memory tier comprises multiple memory cells, and wherein groups of multiple memory cells in each memory tier are in electrical communication with respective word lines extending in the memory tier; forming a first portion of the memory cells by both depositing and etching back multiple materials through pillar openings extending through the stack of tiers, while piers extending through the stack of tiers are filled with a pier fill material; forming a pillar structure extending through the pillar openings; exhuming the pier fill material from the piers to leave pier openings; etching at least the memory tiers to form expanded pier openings at least at the memory tiers; and forming a barrier layer within the expanded pier openings, the barrier extending horizontally around a portion of the of the expanded pier openings and defining, at least in part, respective pier cavities, wherein the word lines are isolated from the pier cavities by the barrier layer; and forming remaining structures of the memory cells through use of the pier cavities.

In Example 31, the subject matter of Example 30 wherein the pillar structure extending through the pillar openings comprises a pillar liner, and a metal pillar.

In Example 32, the subject matter of Example 31 wherein the pillar liner comprises titanium nitride, and wherein the metal pillar comprises tungsten.

In Example 33, the subject matter of any one or more of Examples 30-32 e wherein the barrier layer formed within the expanded pier openings is resistant to etch processes used in forming remaining structures of the memory cells through use of the pier cavities.

In Example 34, the subject matter of any one or more of Examples 30-33 wherein forming the memory tiers comprises exhuming a placeholder material in the memory tiers, and depositing a liner material and word line material between the dielectric tiers, with the liner material extending in part horizontally between the dielectric tiers and the word line material.

In Example 35, the subject matter of Example 34 wherein etching at least the memory tiers to form expanded pier openings at least at the memory tiers, comprises recessing the word line material and liner material of the memory tiers relative to the dielectric tiers.

In Example 36, the subject matter of any one or more of Examples 33-35 wherein the barrier layer comprises Silicon Carbon Nitride.

In Example 37, the subject matter of any one or more of Examples 31-36 optionally include forming of the barrier layer after the pillar and pillar liner are formed; and after forming of the remaining structures of the memory cells, placing the fill material in the pier cavities; wherein at least a portion of the barrier layer remains in the memory array after placing of the fill material in the pier cavities.

In Example 38, any of the methods of Examples 1-18 and 27-17 may incorporate operations or structure formation from another of such examples.

In Example 39, any of the methods of Examples may be adapted to form a memory array as described in any of Examples 19-26.

In Example 40, any of Examples 1-18 and 27-17, or portions thereof may be adapted construct apparatus other than a memory array.

The above description is intended to be illustrative, and not restrictive. For example, the above-described examples (or one or more aspects thereof) may be used in combination with each other. Other embodiments can be used, such as by one of ordinary skill in the art upon reviewing the above description. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A method of forming a memory structure, comprising:
forming a stack of multiple tiers of a first placeholder material alternating with respective tiers of multiple dielectric material tiers;
forming spaced pier openings extending through at least a portion of the stack of multiple alternating tiers;
forming a first barrier layer on surfaces of the stacked tiers defining the pier openings;
depositing pier fill material in the pier openings with the first barrier layer surrounding the pier fill material to form piers;
forming spaced pillar openings extending through at least a portion of the stack of multiple alternating tiers, wherein at least one pillar opening is located between adjacent piers relative to a first axis;
exhuming at least a portion of the first placeholder material of the multiple tiers to form first voids defined by exposed dielectric material tier surfaces and first surfaces of the piers extending between the dielectric material tiers, the first surfaces comprising the first barrier layer;
forming a second barrier material on the first surfaces of the piers to serve as a word line liner in the memory structure; and
depositing word line material in contact with the second layer.

2. The method of forming the memory structure of claim 1, wherein the first barrier layer includes a ceramic material.

3. The method of forming the memory structure of claim 2, wherein the ceramic material is Silicon Carbon Nitride (SiCN).

4. The method of forming the memory structure of claim 2, wherein the second barrier material comprises nitride.

5. The method of forming the memory structure of claim 2, wherein the second barrier material comprises one or more of Silicon Carbon Nitride (SiCN), Aluminum Oxide (Al3O3), Tantalum Pentoxide (Ta2O5), and Zirconium Oxide (ZrO2).

6. The method of forming the memory structure of claim 1, further comprising recessing the second barrier material and the word line material to define the word lines.

7. The method of forming the memory structure of claim 6, wherein the second barrier material is recessed before depositing the word line material, and the wherein the word line material is isolated from the pier fill material by at least the first barrier layer.

8. The method of forming the memory structure of claim 7, wherein both the second barrier material and the word line material are deposited, and then subsequently recessed, and wherein the word line material is isolated from the pier fill material by both the first barrier layer and the second barrier material.

9. The method of forming the memory structure of claim 6, further comprising:
through use of an exhuming process, exhuming the pier fill material from outer piers of three adjacent piers along a first direction, leaving a central pier intact, wherein the first barrier layers adjacent the pier fill material of each of the outer piers limit exposure of the word lines and the second barrier material to the exhuming process;
forming memory cell units on opposite sides of the central pier along the first direction, each memory cell unit comprising at least two variable resistance memory cells on opposite sides of a pillar opening along a second direction, wherein each variable resistance memory cell comprises a first electrode, a variable resistance material, and a second electrode; and
forming conductive pillars in respective pillar openings, the conductive pillars forming portions of bit lines of the memory structure;
wherein the first electrodes are in electrical communication with respective word lines; and
wherein the second electrodes of the memory cells in a memory cell unit are each in electrical communication with respective conductive pillars.

10. The method of forming the memory structure of claim 9, wherein the second electrodes of memory cells in a memory cell unit are integral with one another.

11. The method of forming the memory structure of claim 6, further comprising forming multiple memory cell units comprising:
forming first electrodes in electrical contact with respective word lines, and extending horizontally between surfaces of the first barrier material on adjacent piers;
forming a second placeholder material in physical contact with the first electrodes;
forming second electrodes of each memory cell in physical contact with the second placeholder material and extending generally horizontally between surfaces of the first barrier layer.

12. The method of forming the memory structure of claim 11, further comprising forming conductive pillars extending within respective pillar openings, the conductive pillars in electrical communication with the second electrodes.

13. A method of forming a memory array, comprising:
a stack of multiple tiers of a first placeholder material alternating with respective tiers of multiple dielectric material tiers;
forming spaced pier openings extending through at least a portion of the stack of alternating tiers;
forming a first barrier material on surfaces of the stacked tiers defining the pier openings;
depositing pier fill material in the pier openings with the first barrier material surrounding the pier fill material to form piers;
forming spaced pillar openings extending through at least a portion of the stack of alternating tiers, wherein at least one pillar opening is located between adjacent piers along a first generally horizontal direction;
exhuming at least a portion of the first placeholder material of the multiple tiers to form openings for receiving access line material, the access line material extending in the first direction, the wherein the openings are defined in part by exposed first surfaces of the piers extending between the dielectric material tiers, the first surfaces comprising the first barrier material;
forming a second barrier material on the first surfaces of the piers to serve as first access line liner material in a memory array;
depositing first access line material in contact with the second barrier material;
etching the pillar openings in the memory tiers to form cell recesses to accommodate forming multiple memory cell units in each memory tier, each memory cell unit comprising at least two variable resistance memory cells on opposite sides of a pillar opening in a second direction, wherein each variable resistance memory cell comprises a first electrode, a variable resistance material, and a second electrode;
forming the variable resistance memory cells in the cell recesses, comprising,
forming first electrodes in electrical contact with respective first access lines, the first electrodes extending horizontally between surfaces of the first barrier material on adjacent piers;
forming a second placeholder material in physical contact with the first electrodes;
forming second electrodes of each memory cell in physical contact with the second placeholder material and extending generally horizontally between surfaces of the first barrier material, wherein the second electrodes of at least two memory cells within a respective memory cell unit are formed as a single conductive electrode;
forming conductive pillars within the pillar openings, the conductive pillars in electrical contact with the second electrodes of at least two memory cells within a respective memory cell unit;
through use of an exhuming process, exhuming the pier fill material from outer piers of three adjacent piers along the first direction, leaving a central pier of the three adjacent piers intact, wherein the first barrier material adjacent the pier fill material of each of the outer piers limits exposure of the access lines and access line liners to the exhuming process;
recessing the second placeholder material in the memory cells to define recesses defined at least in part by the respective first electrodes and second electrodes;
depositing variable resistance memory material into the recesses, the variable resistance memory material in electrical contact with the respective first electrodes and second electrodes; and
forming a third placeholder material in place of previously exhumed pier fill material of the outer piers of the three adjacent piers.

14. A memory array, comprising:
a stack of spaced memory tiers, respectively containing multiple cross-point memory cells, and alternating dielectric tiers between the memory tiers;
multiple word lines which extend to respective first pluralities of memory cells in a respective memory tier; and
multiple bit lines which extend at least in part generally vertically and extend to respective second pluralities of memory cells distributed across multiple memory tiers;
wherein the stack of memory tiers and dielectric tiers includes piers which extend through multiple memory tiers and dielectric tiers, and which are separated from contact with respective word lines by at least a first barrier material between the piers and respective word lines.

15. The memory array of claim 14, further comprising a word line liner material also extending between the first barrier material and the respective word lines.

16. The memory array of claim 14, wherein the first barrier material partially surrounds the respective piers and extends vertically through the stack of spaced memory tiers and dielectric tiers.

17. The memory array of claim 14, wherein the first barrier material comprises a ceramic material.

18. The memory array of claim 17, wherein the first barrier material comprises Silicon Carbon Nitride (SiCN).

19. The memory array of claim 17, wherein the first barrier material comprises one or more of Silicon Oxycarbide (SiOC), Aluminum Oxide (Al3O3), Tantalum Pentoxide (Ta2O5), and Zirconium Oxide (ZrO2).

20. The memory array of claim 15, wherein word line liner material comprises nitride.
